(19) United States
(12) Patent Application Publication
(10) Pub. No.: US 2024/0199842 A1
(43) Pub. Date: Jun. 20, 2024

(54) ULTRAVIOLET REFLECTIVE MATERIAL, METHOD FOR PRODUCING SAME, AND RAW MATERIAL COMPOSITION THEREFOR

(71) Applicant: ASAHI RUBBER INC., Saitama-shi, Saitama (JP)

(72) Inventor: Naoto IGARASHI, Saitama-shi (JP)

(73) Assignee: ASAHI RUBBER INC., Saitama-shi, Saitama (JP)

(21) Appl. No.: 18/285,317

(22) PCT Filed: Mar. 15, 2022
(86) PCT No.: PCT/JP2022/011502

§ 371 Date: Oct. 2, 2023

(30) Foreign Application Priority Data
Mar. 30, 2021 (JP) 2021-056905

(51) Int. Cl. C08K 3/01; C08K 3/16; C08K 3/22; C08K 3/28; C08K 3/36

(52) U.S. Cl. CPC C08K 3/01; C08K 3/16; C08K 3/22; C08K 3/28; C08K 3/36; C08K 2003/162; C08K 2003/222; C08K 2003/2227; C08K 2003/282; C08K 2201/003; C08K 2201/019

(57) ABSTRACT

An ultraviolet reflective material having high reflectance in a wavelength region from the short-wavelength ultraviolet region inclusive of 200 nm to the long-wavelength ultraviolet region inclusive of 400 nm, and in particular having high reflectance in an ultraviolet region at 200 to about 315 nm, i.e., from UVC to UVB where reflectance could not be conventionally obtained, among them particularly at 250 nm or below in the short-wavelength ultraviolet region; and does not undergo discoloration/degradation upon irradiation. Ultraviolet reflective materials have ultraviolet reflective layers containing a condensation-cured silicone resin and ultraviolet reflective filler particles of alumina, magnesium hydroxide, calcium fluoride, aluminum hydroxide, aluminum nitride, and the like, and has a reflectance of 60% or more at a wavelength of 405 nm.

### TECHNICAL FIELD

The present invention relates to an ultraviolet reflective material, a method of producing it, and a raw material composition for it, in which the ultraviolet reflective material has high reflectance across the entire ultraviolet radiation ranging from the short-wavelength ultraviolet region inclusive of 200 nm to the long-wavelength ultraviolet region inclusive of 400 nm, wherein the ultraviolet reflective material can be incorporated into ultraviolet emitting devices, including a lighting fixture etc. irradiating ultraviolet radiation, so that ultraviolet light from light sources thereof will be reflected toward the desired irradiation side in order to effectively utilize the ultraviolet radiation; and can also be used as an ultraviolet reflective protection film or ultraviolet reflective member for preventing degradation due to ultraviolet radiation of a support and a surrounding material to which an ultraviolet emitting device is attached.

### BACKGROUND OF THE ART

Ultraviolet emitting diode (UV-LED) with various emission spectra including wavelengths in the ultraviolet region are known to be directly used as a work and operation for sterilization or for curing printing-ink by the high energy of ultraviolet radiation; and also known to be used in a semiconductor luminescent device that modulates spectral properties of irradiating ultraviolet radiation by converting wavelengths using a phosphor.

In particular, the ultraviolet radiation of wavelengths ranging from 400 to 200 nm among the ultraviolet radiation emitted from UV-LED is increasingly used in a variety of applications.

Ultraviolet radiation may be divided into the UVA region (long-wavelength ultraviolet region) of wavelengths ranging from 400 to 315 nm, a UVB region (mid to long-wavelength ultraviolet region) of wavelengths ranging from 315 to 280 nm, and the UVC region (short-wavelength ultraviolet region) of wavelengths ranging from 280 to 100 nm. Although the solar radiation light includes UVA, UVB and UVC, only UVA and UVB passes through the ozone layer and falls on the surface of the earth as sunlight. Meanwhile, UVC, which is not present in sunlight, can be artificially generated for irradiation along with the wavelengths of UVA and UVB as desired.

In environments where such UV-LED is used or where ultraviolet radiation is used, irradiation with ultraviolet radiation may cause problems in that surrounding materials and support substrates other than irradiation targets may be degraded. For example, when a UV-LED is installed in a printed wiring board, the ultraviolet component of the light emitted from the UV-LED may degrade the board.

In order to prevent this degradation of a board, an ultraviolet absorber layer may be provided containing an ultraviolet absorbing agent such as a diazo compound and carbon black etc. For example, Patent Document 1 discloses a dry film having a resin layer on a support. The resin layer is obtained from a curable composition containing an ultraviolet absorbing agent such as carbon black. However, the ultraviolet absorber layer has poor reflective functionality, and thus reflected ultraviolet radiation cannot be effectively utilized.

Meanwhile, a reflective sheet containing an ultraviolet reflective agent may be provided in order to prevent this degradation of a board. For example, Patent Document 2 discloses a reflective sheet including a white-colored base material and a white-colored layer formed on the white-colored base material, and the white-colored layer contains a filler as an ultraviolet reflective agent such as aluminum hydroxide, titanium dioxide, zinc oxide, calcium carbonate, talc, or barium. However, in these conventional reflective sheets, the reflectance of UVB and UVA of wavelengths ranging from 200 to around 315 nm is as very low as about 12 to 30% or less.

The present applicant proposed a reflective base material made of a silicone resin including anatase-type titanium dioxide in attempt to obtain high reflectance in the ultraviolet region while maintaining high reflectance of light such as visible light of long wavelengths and sunlight. However, satisfactory high reflectance could not be obtained in the short-wavelength ultraviolet region and the mid- to short-wavelength ultraviolet region thereby, by JP application No. 2019-204311.

There are demands for an ultraviolet reflective material that can protect surrounding materials such as base materials etc. from ultraviolet radiation to prevent degradation, and that has high reflectance across the entire ultraviolet radiation ranging from the short-wavelength ultraviolet region inclusive of 200 nm to the long-wavelength ultraviolet region inclusive of 400 nm.

### PRIOR ART DOCUMENT

### Patent Document

[Patent Document 1] Japanese Patent Application Publication No. 2019-139245

[Patent Document 2] Japanese Patent Application Publication No. 2013-237183

### SUMMARY OF THE INVENTION

### Problems to be Solved by the Invention

The present invention is made to solve the aforementioned problems. An object of the present invention is to provide an ultraviolet reflective material having high reflectance in a wavelength region ranging from the short-wavelength ultraviolet region inclusive of 200 nm to the long-wavelength ultraviolet region inclusive of 400 nm, in particular having high reflectance in an ultraviolet region of 200 to about 315 nm, i.e., from the short-wavelength ultraviolet region to the mid to short-wavelength ultraviolet region where reflectance could not be obtained conventionally, more particularly in a short-wavelength ultraviolet region of 250 nm or below within the ultraviolet wavelength region. Moreover, an object of the present invention is to provide an ultraviolet reflective material which does not discolor or degrade over time even when irradiated by these types of light; and is excellent in light resistance, heat resistance, weathering resistance, flame retardancy, and thermal conductivity; and is mechanically and chemically stable; and is also excellent in protective performance to suppress degradation due to ultraviolet radiation upon heating; and can maintain high reflectance across the aforementioned broad range of wavelength regions in the entire ultraviolet region for a long time while keeping its initial white color; and is further excellent in adhesion to metal and resin; and can be easily shaped as circuit boards, wiring boards and package cases for various assemblies and the like, in addition to luminescent devices; and can be produced with high production efficiency and low cost.

Moreover, another object of the present invention is to provide a raw material composition enabling formation of an ultraviolet reflective layer on a support of various shapes with a single thick-coating; and a method of simply producing an ultraviolet reflective layer, in which a film-shaped, three dimensionally-shaped, or plate-shaped ultraviolet reflective layer having a thickness sufficient for achieving sufficient reflectance can easily be formed using the raw material composition.

### Means for Solving Problems

An ultraviolet reflective material according to the present invention which is made to achieve the above objects has an ultraviolet reflective layer containing a condensation-cured silicone resin and ultraviolet reflective filler particles so as to have a reflectance of at least 60% at a wavelength of 405 nm thereby.

The ultraviolet reflective filler particles of the ultraviolet reflective material are preferably of alumina, magnesium hydroxide, calcium fluoride, aluminum hydroxide, aluminum nitride, and/or silicon oxide.

The ultraviolet reflective material has a reflectance of at least 60% at a wavelength of, for example, 315 nm.

The above ultraviolet reflective material has a reflectance of at least 60% at a wavelength of, for example, 280 nm.

The ultraviolet reflective material has a reflectance of at least 50% at a wavelength of, for example, 250 nm.

The ultraviolet reflective material has a reflectance of at least 40% at a wavelength of, for example, 200 nm.

The ultraviolet reflective material preferably includes neither titanium oxide, nor potassium titanate, nor barium sulfate.

The ultraviolet reflective filler particles of the ultraviolet reflective material has an average particle diameter as median diameter of, for example, 0.05 to 50 μm.

The ultraviolet reflective layer of the ultraviolet reflective material has a thickness of, for example, 1 to 2000 μm.

The condensation-cured silicone resin of the ultraviolet reflective material is preferably cured by heating.

It is further preferred that the condensation-cured silicone resin of the ultraviolet reflective material includes at least an M unit and a D unit and a T unit as the main ingredients, among the T unit as a mono-organosiloxy unit consisting of an RSiO_{3/2} unit (wherein an organo group R is the same or different, and is a group from an alkyl group, an aryl groups, or a crosslinkable functional group), a Q unit as a siloxy unit consisting of an SiO₂ unit, the M unit as a tri-organosiloxy unit consisting of an R₃SiO_{1/2} unit (wherein R is the same as above), and the D unit as a di-organosiloxy unit consisting of an R₂SiO unit (wherein R is the same as above).

The ultraviolet reflective layer of the ultraviolet reflective material is applied on a film-shaped, plate-shaped, or three dimensionally-shaped support formed of, for example, any one of inorganic material selected from alumina, glass, aluminum, copper, nickel, aluminum, aluminum nitride, copper, stainless steel, and ceramics, or any one of organic material selected from imide resin, bismaleimide-triazine resin, glass fiber-containing epoxy resin, paper phenol resin, Bakelite, polyethylene terephthalate resin, polybutylene terephthalate resin, polyacrylonitrile resin, polycarbonate resin, fluororesin, polyimide resin, polyphenylene sulfide resin, aramid resin, polyether ether resin, polyetherimide resin, liquid crystal polymer, polyether sulfone resin, cycloolefin resin, silicone rubber, and silicone resin.

The ultraviolet reflective material may have an electrically conductive pattern attached on the front surface or back surface of the ultraviolet reflective layer.

In the ultraviolet reflective material, the electrically conductive pattern may be exposed at a polished surface of the ultraviolet reflective layer covering the support having the electrically conductive pattern.

The ultraviolet reflective layer of the ultraviolet reflective material may partially cover the support having the electrically conductive pattern.

The electrically conductive pattern of the ultraviolet reflective material is, for example, a metal film.

In a method of producing the ultraviolet reflective layer according to the present invention which is made to achieve the aforementioned objects, a condensation-curable silicone resin raw material curable into a condensation-cured silicone resin by condensation and ultraviolet reflective filler particles are mixed for dispersion and inclusion to prepare a liquid, or greasy and viscus or plastic raw material composition for an ultraviolet reflective material; and the raw material composition is then polymerized into the silicone resin by three-dimensional crosslinking to form a film-shaped, three-dimensionally shaped, or plate-shaped ultraviolet reflective layer, wherein the ultraviolet reflective layer has a reflectance of at least 60% at a wavelength of 405 nm after the curing.

A raw material composition of the ultraviolet reflective material according to the present invention which is made to achieve the above objects contains a condensation-curable silicone resin raw material curable into a condensation-cured silicone resin by condensation and ultraviolet reflective filler particles with dispersion; and is liquid, greasy and viscus or plastic for forming a ultraviolet reflecting layer having a reflectance of at least 60% at a wavelength of 405 nm after the curing.

### Effects of the Invention

In the ultraviolet reflective material according to the present invention, the ultraviolet reflective filler particles such as those of alumina, magnesium hydroxide, calcium fluoride, aluminum hydroxide, aluminum nitride, and silicon oxide are contained in the ultraviolet reflective layer in a dispersed manner along with the condensation-cured silicone resin, the ultraviolet reflective filler particles have a higher refractive index and higher ultraviolet reflectance than the condensation-cured silicone resin. The ultraviolet reflective material according to the present invention, therefore, has high reflectance at the ultraviolet region, particularly at a near-ultraviolet region of 200 to 400 nm, more particularly at an ultraviolet region of 200 to about 315 nm, i.e., from the short-wavelength ultraviolet region to the mid to short-wavelength ultraviolet region where reflectance could not be obtained conventionally, even more particularly in a short-wavelength ultraviolet region of 250 nm or below, preferably lower than 250 nm. In addition to that, high reflectance can be achieved even in the visible light region such as at an emission wavelength of about 340 to 500 nm in the case of an LED light source including blue light. Moreover, high reflection efficiency can be achieved for high-intensity light in a broad range of wavelengths of near-infrared up to, for example, a longer wavelength of 1000 nm. Excellent thermal conductivity and degradation resistance can also be obtained. Furthermore, the present ultraviolet reflective material has opacity, and does not cause light leakage, and provides excellent ultraviolet protection.

The ultraviolet reflective layer of the ultraviolet reflective material includes ultraviolet reflective filler particles of alumina, magnesium hydroxide, calcium fluoride, aluminum hydroxide, aluminum nitride, silicon oxide, or the like which can very efficiently reflect light in a wavelength region of 200 to 400 nm, particularly in a short to mid-wavelength ultraviolet region of 200 to about 315 nm, more particularly includes ultraviolet reflective filler particles in a powder form of alumina, magnesium hydroxide, silicon oxide (silica), or the like. This enables high reflectance in an ultraviolet region of 200 to 400 nm, particularly in an ultraviolet region of 200 nm to about 315 nm, i.e., from the short-wavelength ultraviolet region to the mid-wavelength ultraviolet region where reflectance could not be obtained conventionally, even more particularly in a short-wavelength ultraviolet region of 250 nm or below. Moreover, this can also provide sufficient protection from light degradation due to ultraviolet radiation.

The ultraviolet reflective material can efficiently reflect not only light in a wavelength region of 380 to 405 nm in the visible light region but also light in a wavelength region of 365 nm to 240 nm in the ultraviolet region among irradiation wavelengths of commercially available LEDs.

The ultraviolet reflective material does not undergo discoloration/degradation due to ultraviolet radiation, particularly due to light and heat from ultraviolet radiation, and shows high reflection efficiency in a region ranging from ultraviolet to near infrared radiation, in particular in the ultraviolet region, and further can maintain light resistance, heat resistance, weathering resistance, flame retardancy, and stability at high performance level, leading to excellent durability.

The ultraviolet reflective layer used as a reflective layer in the ultraviolet reflective material is formed of a stable condensation-cured and three-dimensionally crosslinked silicone resin which is resistant to decomposition and deterioration due to light and heat, preferably formed of a condensation-cured silicone resin including an acyclic or mesh-structured phenylsiloxy repeating unit or methylsiloxy repeating unit as the main ingredient in the main chain. Therefore, it is much more stable against light and heat than epoxy resin and others which may discolor easily due to heat and light, and is not only excellent in reflection efficiency but also in light resistance over time, particularly excellent in light resistance against ultraviolet radiation or high-intensity light, more particularly excellent in light resistance against near-infrared radiation; and also excellent in heat resistance; durability such as weathering resistance; flame retardancy; and workability. Further, it does not undergo discoloration for a long time, and is resistant to degradation. Thereby, the ultraviolet reflective material can protect a support and a surrounding material from ultraviolet radiation irradiated while maintaining reflectance over time, and can prevent degradation due to those types of ultraviolet radiation for a long time. The present ultraviolet reflective material can maintain high reflectivity because the ultraviolet reflective layer remains in its initial white-colored state even after a long period of time.

The present ultraviolet reflective material does not undergo discoloration or degradation even after long-term exposure to high-intensity light-emitting diodes and the resulting high temperature. This can be achieved by virtue of the condensation-cured siloxy repeating unit that is stable against heat and light.

The present ultraviolet reflective material has high reflectance for ultraviolet radiation by virtue of the ultraviolet reflective filler particles, leading to effective use of ultraviolet radiation with excellent reflection efficiency, and further shows a high reflection effect for visible light. Moreover, no cracks, fissures, tears, and the like are caused in the ultraviolet reflective material by light degradation due to ultraviolet radiation and the like and changes in thermal expansion due to heating and cooling, and thus no damage will occur. Furthermore, the ultraviolet reflective material can protect a support and a surrounding material from ultraviolet radiation irradiated, and can prevent degradation due to those types of ultraviolet radiation.

The present ultraviolet reflective material can selectively keep high reflectance in a desired wavelength region by appropriately selecting the types of the ultraviolet reflective filler particles to increase corresponding functionalities depending on the intended use.

When the ultraviolet reflective filler particles are dispersed in the ultraviolet reflective layer and surface-exposed, the present ultraviolet reflective material can improve reflectance for not only visible light but also light in an ultraviolet region of 200 nm or higher, particularly for light in an ultraviolet region at wavelengths where reflectance could not be conventionally obtained such as a wavelength of 200 to 315 nm, leading to improved irradiation effects when installed in a luminescent device.

In particular, it is preferable to use a silicone raw material with a relatively low refractive index, such as condensation-cured methyl silicone and phenyl silicone etc., since the difference is large in the refractive index between the ultraviolet reflective filler particles and the silicone raw material with a low refractive index in contact with the surfaces of the ultraviolet reflective filler particles, leading to efficient reflection of not only visible light but also ultraviolet radiation, particularly of ultraviolet radiation. Therefore, light can be efficiently reflected and emitted from the surfaces of the ultraviolet reflective filler particles exposed.

Moreover, when the ultraviolet reflective material has the so-called MDT structure in which the silicone resin including the M unit, the D unit, and the T unit as the main ingredients is three-dimensionally crosslinked, higher ultraviolet reflectance can be obtained. Moreover, the ultraviolet reflective layer having that silicone resin can be formed on a support in a form of a film-shape, a three-dimensional shape, or a plate-shape. Moreover, a liquid composition or a greasy or plastic raw material composition including the ultraviolet reflective filler particles and the condensation-curable silicone resin raw material can be applied as thick as up to 2000 μm, and then allowed to undergo three-dimensional crosslinking and curing to form the ultraviolet reflective layer. Therefore, in the ultraviolet reflective material, the ultraviolet reflective layer can be formed in any shapes according to a wiring board, assembly, and package case of a luminescent device and an optical device emitting not only visible light but also ultraviolet radiation, showing broad versatility. Moreover, the raw material composition can also be used for forming a reflective material which can also serve as an adhesive for bonding a component such as a package case etc. to a support.

A small amount of the Q unit may be included within a range where the effects of the prevent invention are not interfered as long as each molar quantity of three-dimensionally crosslinked Si atoms is 1 to 4 in the silicone resin, and the silicone resin is of a condensation-cured type having ether-linkage via oxygen atoms or crosslinkable functional groups, and have the so-called MDT structure as main structure. This makes the raw material composition of the condensation-cured silicone resin highly viscus, enabling thick coating and shaping.

The ultraviolet reflective material can have an electrically conductive pattern.

The ultraviolet reflective material can be produced in a simple and easy process, and homogenous and high-quality products can be produced precisely, reliably, and in large quantities at low cost. Therefore, its productivity is high.

According to the method of producing the ultraviolet reflective material of the present invention, the raw material composition of the ultraviolet reflective material, which is high viscus, can be applied as thick as 2000 μm without dripping. Moreover, according to this production method, an ultraviolet reflective material showing a synergistic effect between reflection efficiency and protection can be produced when the ultraviolet reflective layer is applied on a support, regardless of the material, the shape, the degree of surface unevenness or smoothness, narrowness, hardness, softness, and thickness of the support.

The raw material composition of the ultraviolet reflective material can be polymerized into three-dimensionally crosslinked silicone resin by a coating process such as spraying and application to form the ultraviolet reflective layer in a form from a thin film of 1 to 10 μm, to a thick film or plate of 2000 μm, or a three-dimensional shape.

To form the ultraviolet reflective layer using the raw material composition of the ultraviolet reflective material, the raw material composition may be applied directly, or, after adjustment to an appropriate viscosity, by known application methods such as screen printing, bar coater, roll coater, reverse coater, gravure coater, air knife coater, spray coater, and curtain coater, and for even thinner applications, by high-precision offset coater and multistage roll coaters etc. A predetermined shape can be formed by this thick coating at a single attempt without need of repeated application and drying.

Moreover, even if appropriately diluted with a solvent, the raw material composition of the ultraviolet reflective material does not cause a decrease in viscosity upon curing by heating unlike the case with raw material compositions such as epoxy resins etc. Therefore, the ultraviolet reflective layer can be directly cured as it is without deformation during heating to form an ultraviolet reflective layer having a desired shape and thickness.

Such polymerization can be easily completed by heating, humidifying, ultraviolet irradiation, and, if necessary, under pressure to form an ultraviolet reflective layer having excellent adhesion to a support. Heat curing is, however, preferred therefor. When ultraviolet-cured and condensation-cured silicone resins are used, a reaction initiator, which initiates curing upon ultraviolet irradiation, remains in a reflective layer. This may cause ultraviolet radiation to be absorbed, resulting in insufficient reflectance. Curing proceeds over time during use, and cracking and detachment may be observed in a reflective layer. The more cracking and detachment problems may increasingly occur, the more it proceeds toward complete curing.

In the present method of producing an ultraviolet reflective material, use of a raw material composition in which ultraviolet reflective filler particles are contained in the condensation-curable silicone resin raw material enables stable storage under room temperature for a long period of time. Polymerization, which is not initiated until the start of heating, but surely initiated by heating and completed in a short time to form the ultraviolet reflective layer, contributes to improve production efficiency.

### BRIEF DESCRIPTION OF THE DRAWINGS

FIG. 1 shows a schematic cross-sectional view of a luminescent device including an ultraviolet reflective material according to the present invention.

FIG. 2 shows a schematic cross-sectional view of a luminescent device including another ultraviolet reflective material according to the present invention.

FIG. 3 shows a correlation between irradiation wavelengths and reflectance for an ultraviolet reflective material according to the present invention and a conventional ultraviolet reflective material which does not apply the present invention.

FIG. 4 shows a correlation between irradiation wavelengths and reflectance for an ultraviolet reflective material according to the present invention and a conventional ultraviolet reflective material which does not apply the present invention.

FIG. 5 shows a correlation between irradiation wavelengths and reflectance for an ultraviolet reflective material according to the present invention.

FIG. 6 shows a correlation between irradiation wavelengths and reflectance for various plates.

FIG. 7 shows a correlation between irradiation wavelengths and reflectance for an ultraviolet reflective material according to the present invention and a conventional ultraviolet reflective material which does not apply the present invention.

### MODE FOR CARRYING OUT THE INVENTION

Hereinafter, Examples of the present invention will be described in detail, but the scope of the present invention shall not be limited to these Examples.

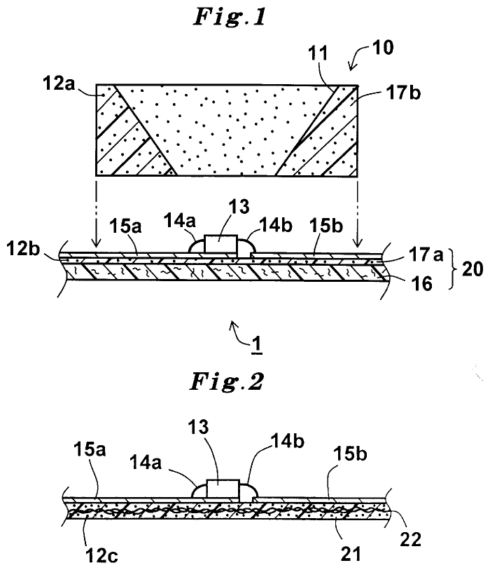

First, preferred embodiments of ultraviolet reflective materials 10 and 20 according to the present invention will be described in detail with referring to FIG. 1.

The ultraviolet reflective materials 10 and 20 of the present invention, which are integrated into a lighting fixture 1 as a type of a luminescent device as shown in FIG. 1, have copper foils 15a and 15b corresponding wiring patterns for mounting a light-emitting diode 13 as a light-emitting device; an ultraviolet reflective material 20 as an ultraviolet reflective plate which is a wiring board having an ultraviolet reflective layer 17a provided on a support 16; and another ultraviolet reflective material 10 as a package case surrounding the light-emitting device 13.

In the ultraviolet reflective materials 10 and 20 as a package case and a wiring board, respectively, the ultraviolet reflective layers 17a and 17b, in which ultraviolet reflective filler particles having a higher refractive index than a condensation-cured silicone resin are contained in a dispersed manner in the condensation-cured silicone resin, is formed on the support 16 in a form of a film shape, a three-dimensional shape, or a plate shape. The ultraviolet reflective material 10 may be provided as the ultraviolet reflective layer 17b. The ultraviolet reflective material 20 may be provided as the support 16 and the ultraviolet reflective layer 17a, but may consist only of the ultraviolet reflective layer 17a.

In the ultraviolet reflective layers 17a and 17b of the ultraviolet reflective materials 10 and 20, the silicone resin is exposed, where at least any selected from the ultraviolet reflective filler particles 12a and 12b, for example, alumina, magnesium hydroxide, calcium fluoride, aluminum hydroxide, aluminum nitride, and silicon oxide are contained and partially exposed.

In such ultraviolet reflective materials 10 and 20, the ultraviolet reflective layers 17a and 17b, which color is white and has opacity, can prevent leakage of light. It has high reflectance of ultraviolet radiation at wavelengths of 200 to 400 nm, particularly 200 to about 315 nm. Furthermore, it has reflective performance from the visible light region to the near-infrared region at that site.

These ultraviolet reflective materials 10 and 20 have a reflectance of 60% or more, preferably 64% or more at a wavelength of 405 nm. Further, it has a reflectance of at least 60%, preferably 61% or more at a wavelength of 315 nm; a reflectance of at least 60% at a wavelength of 280 nm; a reflectance of at least 50% at a wavelength of 250 nm, preferably 60% or more, more preferably 65% or more; and/or at least 40% at a wavelength of 200 nm, preferably at least 50% or more, more preferably at least 60% or more, even more preferably at least 70% or more, still more preferably at least 78% or more.

As shown above, the ultraviolet reflective materials 10 and 20 have highly reflective by virtue of the ultraviolet reflective layers 17a and 17b, and can maintain their white color without discoloration even after long-term exposure to high-intensity light, and further has high mechanical strength, excellent light resistance, heat resistance, and weathering resistance, leading to excellent durability. The ultraviolet reflective filler particles 12a and 12b contained in the ultraviolet reflective layers 17a and 17b of the ultraviolet reflective materials 10 and 20 preferably contain at least any inorganic powder as the main ingredient selected from alumina, magnesium hydroxide, calcium fluoride, aluminum hydroxide, aluminum nitride, and silicon oxide. Among them, it is even more preferred to contain alumina, magnesium hydroxide, and/or silicon oxide, which can sufficiently reflect light at wavelengths of 200 to 315 nm, as the main ingredient, leading to particularly significant reflectance at 250 nm or below. For silicon oxide, ultraviolet reflective filler particles of quartz are preferred.

The ultraviolet reflective filler particles 12a and 12b have an average particle diameter of, for example, 0.05 to 50 μm, preferably 0.05 to 10 μm by median diameter, i.e., a particle diameter corresponding to the median value of the distribution. The ultraviolet reflective filler particles 12a and 12b can be polyhedron spherical, crushed, or spherical in particle shape. Particles with an aspect ratio of 2 or higher are preferred to be used because cracking of the ultraviolet reflective layers due to light degradation and changes in thermal expansion by heating and cooling can be suppressed.

The ultraviolet reflective layers 17a and 17b are not limited to those formed in a single layer, but may be a laminated body formed to be laminated with multiple layers. Therefore, in single layers of the ultraviolet reflective layers 17a and 17b, the ultraviolet reflective filler particles 12a and 12b may include a mixture of multiple types of inorganic powders, or each layer may have different ultraviolet reflective filler particles 12a and 12b, or different types of other inorganic powders separated by layers may be included.

In the ultraviolet reflective layers 17a and 17b of the ultraviolet reflective materials 10 and 20, the ultraviolet reflective filler particles 12a and 12b are included in an amount of 3 to 400 parts by mass, preferably 40 to 350 parts by mass, more preferably 80 to 250 parts by mass relative to 100 parts by mass of the condensation-cured silicone resin. When the amount of the ultraviolet reflective filler particles 12a and 12b is more than 400 mass % in the condensation-cured silicone resin, they are not dispersed homogeneously. When less than 3 mass %, they lack ultraviolet reflectivity, whiteness, and opacity.

The reflectance is extremely high in the ultraviolet region, particularly at 200 to about 315 nm, when the ultraviolet reflective filler particles 12a and 12b such as alumina particles etc. are dispersed in the condensation-cured silicone resin in the ultraviolet reflective layers 17a and 17b as compared to the case where the condensation-cured silicone resin is provided to an alumina plate. The details of the reason for this are not necessarily clear, but it is assumed that the surface area according to the number of dispersed particles of the ultraviolet reflective filler particles such as alumina particles etc. contribute to high reflectance in contrast to an alumina plate where it is the area of the plate that ultraviolet radiation is reflected at. The surface area of the alumina particles is larger than the area of the alumina plate, leading to diffused reflection.

The ultraviolet reflective filler particles 12a and 12b may be modified by preliminary surface treatment with a surface treatment agent. Surface treatment agents include, for example, silane coupling agents. Surface treatments can improve the dispersibility of the ultraviolet reflective filler particles in the condensation-cured silicone resin to further improve the reflectance of the ultraviolet reflective layers 17a and 17b, or to strengthen the interaction between the condensation-cured silicone resin and the ultraviolet reflective filler particles for further improving the mechanical strength and detachment strength of the ultraviolet reflective layers 17a and 17b.

In addition to the ultraviolet reflective filler particles 12a and 12b, another inorganic powders may be included in the ultraviolet reflective layers 17a and 17b. Examples of another inorganic powder include thickener powder, e.g., fine silicon oxide particles having an average particle size of 1 nm to 100 nm. Another inorganic powders may be used in an amount of 0.5 to 50 parts by mass relative to 100 parts by mass of the condensation-cured silicone resin. However, it is preferred that none of titanium dioxide, for example, anatase-type or rutile-type titanium dioxide, potassium titanate, or barium sulfate are included. This is because the powders of titanium dioxide, potassium titanate, or barium sulfate have high reflectance in the range of 420 to 1000 nm, while they show light absorption in the ultraviolet range, particularly in the range of 200 to 380 nm, resulting in lower reflectance.

To increase the scattering of light on the surfaces of the ultraviolet reflective layers 17a and 17b for improving reflectance, a phosphor may be included in the ultraviolet reflective layers 17a and 17b along with the ultraviolet reflective filler particles, and these particles are, if necessary, exposed from the surfaces to allow direct light reflection or emission of fluorescence or phosphorescence that is emitted when the excited state caused by the transition from the ground state due to light returns back to the ground state. As such phosphors, inorganic and organic fluorescent substances such as halogenated phosphate phosphors, rare earth metal-containing phosphors such as Eu etc., and YAG (yttrium aluminum garnet) phosphors; and fluorescent brightening materials (benzoxazole-based fluorescent brightening materials), are used.

The surfaces of the ultraviolet reflective layers 17a and 17b of the ultraviolet reflective materials 10 and 20 may reflect light like a mirror, but they may have non-mirror surfaces such as of an uneven shape in the order of nanometers such as 100 nm to 10 μm to micrometers, a prism shape such as pyramid or rectangular cylinder, a pearskin finish-like shape by etching treatment, sandblasting treatment, or the like. In that case, incident light is diffused in all directions, improving diffuse reflectance as compared to reflection in a specific direction as in a mirror surface. This reduces uneven reflection of light and increases whiteness to further improve reflection efficiency.

For example, the condensation-cured silicone resin in the ultraviolet reflective layers 17a and 17b of these ultraviolet reflective materials 10 and 20 preferably includes at least an M unit and a D unit and a T unit as the main ingredients in any combinations thereof, among a tri-organosiloxy unit (a R₃SiO_{1/2} unit: the M unit), a mono-organosiloxy unit (a RSiO_{3/2} unit: the T unit), a siloxy unit (an SiO₂ unit: a Q unit) (wherin the organo group R is the same or different, and is an alkyl group such as a methyl group or a phenyl group). Among these combinations, an MDT silicone resin having three-dimensional crosslinking formed are preferred as the condensation-cured silicone resin because of its high reflectance. Condensation-cured silicone resins include those in which hydroxysilyl groups in a silanol compound are polymerized together by thermal dehydration condensation, and those in which alkoxysilyl groups in an alkoxysilane compound or a hydroxysilyl group in a silanol compound and an alkoxysilyl group in an alkoxysilane compound are polymerized together by dealcoholization. Examples include condensation-cured silicone resins comprising polymethylsiloxane and/or polyphenylsiloxane with a refractive index of about 1.40 to 1.43, for example 1.41. In the ultraviolet reflective layers 17a and 17b, the ultraviolet reflective filler particles 12a and 12b having a higher refractive index are contained in a mesh-like structure crosslinked in a mesh-like manner of a silicone resin in which the main chains as polymethylsiloxane and/or polyphenylsiloxane are three-dimensionally crosslinked together.

For this condensation-cured silicone resin, a heat-cured type is more reflective than an ultraviolet-cured type,

The mole number ratios of the M unit:the D unit:the T unit are preferably 1 to 4:1 to 4:2 to 8, more preferably 1 to 3:2 to 4:3 to 7 in the condensation-cured silicone resin. The Q unit may be included within a range where the effects of the present invention are not interfered as long as the M unit, the D unit, and the T unit are included as the main ingredients. In that case, the mole number ratio of the Q unit preferably does not exceed each of the mole number ratios of the M unit:the D unit:the T unit.

For example, such condensation-cured silicone resins, for example, those including an acyclic monomethylsiloxy repeating unit, a dimethylsiloxy repeating unit, and a trimethylsiloxy unit as the main ingredients in the main chain, are more specifically polymers having a degree of polymerization of about 5000 to 10000 and an average molecular weight of about 400,000 to 800,000.

Raw material components of the condensation-cured silicone resins include, for example, KR-220LP (Product name from Shin-Etsu Chemical Co., Ltd.) as a methyl-based silicone resin raw material component; X-21-5841 (Product name from Shin-Etsu Chemical Co., Ltd.) having hydroxy groups at the both ends as a diol-based silicone resin raw material component; KR-500 and X-40-9250 (both are Product names from Shin-Etsu Chemical Co., Ltd.) as an alkoxy-based silicone resin raw material component. They have a three-dimensionally crosslinked structure, and can form a condensation-cured silicone resin, showing hard or soft and inelastic or rubber elastic properties.

In general, silicone resins include a variety of cured types such as addition reaction-cured, organic peroxide-cured, and condensation-cured. Among them, condensation-cured silicone resins of a condensation-cured type are used in the present invention. When comparing addition-cured silicone resins with condensation-cured silicone resins, condensation-cured silicone resins can provide higher reflectance than addition-cured silicone resins, especially in a region including UVC (the short-wavelength ultraviolet region) where addition-cured silicone resins typically provide lower reflectance. They show significantly different reflectance.

Addition-cured silicone resins and organic peroxide-cured silicone resins show low hardness of the resulting coating film and absorption of light in the ultraviolet region, whereas condensation-cured silicone resins show high hardness of the resulting coating film and low absorption of light in the ultraviolet region. Therefore, condensation-cured silicone resins are particularly preferred for the ultraviolet reflective material according to the invention.

The hardness of the ultraviolet reflective layers 17a and 17b is 30 or more, more preferably 50 or more in terms of the Shore A hardness, and/or 6 H or less, preferably 4 or less in terms of the pencil hardness. When the hardness is less than 30 in terms of the Shore A hardness, the layers may be too soft and easily scratched, and dust may more likely adhere. On the other hand, when the hardness is higher than 6H in terms of the pencil hardness, the layers may be too hard and may crack when bent.

The hardness of the ultraviolet reflective layers 17a and 17b containing the ultraviolet reflective filler particles in such a condensation-cured silicone resin may be appropriately selected according to the case where the ultraviolet reflective layers 17a and 17b are used alone or the type of the support 16 when the ultraviolet reflective layers 17a and 17b are provided on the support 16. When the support 16 is like a film, it may be deformed freely, but it needs be hard enough not to undergo buckling and scratching upon deformation. If extremely hard, the difference in thermal expansion coefficients between the support 16 and the ultraviolet reflective layers 17a and 17b may cause detachment or cracking between the support 16 and the ultraviolet reflective layers 17a and 17b. In general, when the hardness is 90 or less in terms of the Shore A hardness by measurement with a JIS A hardness meter, 30 or less in terms of the Shore D hardness by measurement with a JIS D hardness meter, sense of being rubber is felt by touch. In contrast, a Shore D hardness of 50 or less can be considered as being rubber in the present invention. A Shore D hardness between 40 and 60 is considered as a soft resin reflective layer. A value of more than 60 is no longer considered as rubbery, and considered as a highly resin-like reflective layer.

In addition to the raw material component of the condensation-cured silicone resin, the raw material composition of the ultraviolet reflective material may contain an adhesion-conferring component having a reactive functional group such as an epoxy group, an alkoxysilyl group, a carbonyl group, and a phenyl group, and if necessary, solvent in order to further improve adhesion and bonding with the support.

The condensation-cured silicone resin used to form the ultraviolet reflective layers 17a and 17b of the ultraviolet reflective material according to the present invention may coexist with another crosslinkable functional group-containing silanol compound which can be three-dimensionally crosslinked with a raw material component of the condensation-cured silicone resin, for example, a blocked silanol compound and a crosslinkable functional group-containing silane coupling agent.

Three-dimensionally crosslinked condensation-cured silicone resins can be obtained, for example, by three-dimensionally crosslinking and curing of the raw material components of the condensation-cured silicone resins. More specifically, the condensation-cured silicone resin are formed by curing under normal or reduced pressure at room temperature or under heating.

Examples of organopolysiloxane as described above include those represented by the following average unit formula:

R¹ₐSiO_{(4-a)/2}

wherein R¹ is an unsubstituted or substituted monovalent hydrocarbon group preferably having 1 to 10 carbon atoms, particularly 1 to 8 carbon atoms, and a represents a positive number of 0.8 to 2, particularly 1 to 1.8. In the formula, examples of R include alkyl groups such as methyl, ethyl, propyl, and butyl groups etc .; aryl groups such as phenyl and tolyl groups etc.; halogen-substituted hydrocarbon groups such as chloromethyl, chloropropyl, and 3,3,3-trifluoropropyl groups etc. in which some or all of hydrogen atoms attached to carbon atoms thereof are replaced with halogen atoms; or cyano group-substituted hydrocarbon groups such as 2-cyanoethyl group etc. and the like in which some or all of hydrogen atoms attached to carbon atoms thereof are replaced with cyano groups.
R¹ may be the same or different, but R¹ is preferably a methyl group, particularly a methyl group so that a dimethylsiloxy group represents the main ingredient, in terms of development of reflectivity, heat resistance, and durability etc.

This silicone resin is three-dimensionally crosslinked such that the Si atom of a repeating unit is attached to the Si atom of the next repeating unit via an oxygen atom or a crosslinkable functional group.

The ultraviolet reflective materials 10 and 20 may be mounted on electrical components, and thus it is even more preferably formed of a condensation-cured silicone resin from which low molecular weight siloxane, for example, cyclic low molecular weight siloxane having 4 to 10 (D4 to D10) siloxy group repeating units contained in the condensation-cured silicone resin potentially responsible for electrical contact failure and hazing is pre-removed to less than 300 ppm, preferably less than 50 ppm. Specifically, a commercially available raw material composition of an ultraviolet reflective material having a reduced amount of low molecular weight siloxane may be used. Alternatively, a raw material of a condensation-cured silicone resin may be used from which low molecular weight siloxane is removed by performing heat treatment such as oven heat treatment (for example, heat treatment at 200° C. for 4 hours), vacuum heat treatment (heating under vacuum at 200° C. for 2 hours) etc. In addition to these treatments, ultrasonic solvent extraction or other means can be used to remove low molecular weight siloxanes from a formed product. Although low molecular weight siloxane can be removed from a raw material of a condensation-cured silicone resin, low molecular weight siloxane is preferably removed from a formed product because this enables removal to a lower level. When the condensation-cured silicone resin contains a small amount of volatile residual low molecular weight siloxane which has low surface tension and easily repels molten metal and other substances, a wiring process of soldering between metal such as an electrically conductive pattern and a conducting wire leading to an element such as a light-emitting diode and the like can be performed easily.

The raw material composition of the ultraviolet reflective material may be the so-called two-liquid component composition where two separate liquid components are prepared as in common curable silicone resin compositions, and the two liquid components are mixed for curing when used, but it is preferably a one-liquid component composition in terms of workability etc. when using the composition. However, a two-component composition or three-component composition may be used in view of the liquid stability of the silicone resin raw material composition. The silicone resin raw material composition can be cured under normal conditions, and can also be cured by ultraviolet irradiation, but preferably crosslinked by heating to allow hardness or softness and inelasticity or rubber elasticity to be developed.

In the ultraviolet reflective materials 10 and 20, the ultraviolet reflective layer 17a may be formed on an untreated surface of the support 16. The adhesion strength between the support 16 and the ultraviolet reflective layer 17a is high because the excellent adhesiveness and bonding with the condensation-cured silicone resin can be achieved during curing by three-dimensional crosslinking of the raw material of the condensation-cured silicone resin.

Although pre-surface treatment of the support is not always necessary, a reflective layer may be formed on a support where a surface to be coated of the support is pre-surface treatment by treatment such as corona discharge treatment, plasma treatment, ultraviolet treatment, flame treatment, Itro treatment, or surface roughening treatment before a coating process of the raw material composition of the ultraviolet reflective material. This is preferred because the ultraviolet reflective layers 17a and 17b can be adhered and bonded more firmly on the treated surface of the support 16. These surface treatments are preferably be performed immediately before application of the raw material composition of the ultraviolet reflective material on the support.

The support 16 may be firmly bonded with the ultraviolet reflective layer 17a as described above by corona discharge treatment, plasma treatment, ultraviolet irradiation treatment, flame treatment, or Itro treatment, or any of the surfaces via which an adhesive body is to be formed may be surface treated.

To bond the support 16 with the ultraviolet reflective layer 17a even more firmly by contacting, a functional silane compound such as a silane coupling agent may be used on both or one of the surfaces via which an adhesive body is to be formed. Such functional silane compounds include polysiloxane containing a reactive group which is highly reactive with an OH group.

Examples of the reactive group-containing polysiloxane include compounds represented by the following chemical formula (1):

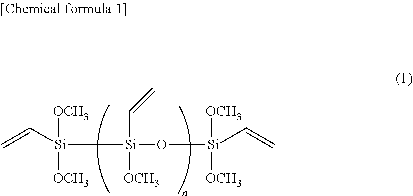

wherein n is 3 to 4, and at least any of the reactive groups —OCH₃ reacts with a functional group on the surfaces of a reflective layer and a metal foil layer, for example, with an OH group. This compound may have repeating units that are block-copolymerized or random-copolymerized. It may be dipped into a solution of vinylalkoxysiloxane homopolymer such as this vinylmethoxysiloxane homopolymer, or coated with that solution, or it may be dipped into a platinum catalyst suspension liquid and allowed platinum catalyst to retain on vinyl groups of the active silyl groups for improving reactivity.

The raw material composition of the ultraviolet reflective material may be prepared by adding an appropriately adjusted addition amounts of the condensation-curable silicone resin raw material and the ultraviolet reflective filler particles such as alumina and the like, and, depending on the purpose and if desired, an appropriately adjusted addition amounts of an organic solvent and a reactive diluent. Depending on applications, it may be suitably adjusted in terms of plasticity so as to be a liquid, greasy, or plastic substance which may be defined by plasticity. For example, a resist ink in a liquid form for spraying, dispensing, or screen printing preferably has a viscosity of 0.5 to 500 Pa·s, more preferably 10 to 200 Pa·s. When formed by heat press, the raw material composition of the ultraviolet reflective material is preferably used as a millable or plastic substance having a plasticity of 100 to 500 mm/100 based on the international standard ISO 7323.

Optionally, the raw material composition of the ultraviolet reflective material may contain an organic solvent to improve storage stability and coating performance, to control coating volume, and to adjust viscosity, and the like. An organic solvent, if used, is preferred added in an amount of 100 to 10000 parts by mass relative to 100 parts by mass of the condensation-curable silicone resin raw material. When the amount of an organic solvent is less than this range, threading and clogging may occur during application or printing, resulting in reduced productivity. On the other hand, when the amount of an organic solvent is higher than this range, thick coating cannot be achieved, or sufficient reflectance cannot be obtained with a single application. An organic solvent may be appropriately adjusted for use depending on various coating methods, required reflectance, film thickness, and viscosity. As an organic solvent, used are those that do not react with the condensation-curable silicone resin raw material, the ultraviolet reflective filler particles such as alumina etc., a cross-linker and a reaction inhibitor to be added as needed. Specifically, examples include toluene, xylene, ethyl acetate, acetone, methyl ethyl ketone, and hexane. When viscosity is adjusted with an organic solvent, the filling concentration of the ultraviolet reflective filler particles relatively decreases by the addition of the organic solvent, but once the organic solvent volatilizes after curing, the filling concentration of the ultraviolet reflective filler particles returns to a high concentration as was before viscosity adjustment, allowing for printing of thin coating film at high concentration.

Reactive diluents, which are particularly used to adjust the viscosity of one-liquid component adhesives, do not volatilize unlike organic solvents, and will cure into a silicone resin as it is. Reactive diluents include, for example, KR-510 (Product name from Shin-Etsu Chemical Co., Ltd.). Reactive diluents do not necessarily be used, but if used, are added in an amount of 0.1 to 30 parts by mass, preferably 1 to 20 parts by mass relative to 100 parts by mass of the silicone resin raw material. When the amount added is much smaller that these ranges, viscosity cannot be adjusted, and when the amount added is much larger than these ranges, the physical properties of the resulting silicone resin is weak. Reactive diluents will cure into a condensation-cured silicone resin together, compare to causing localized necking by post-volatilization after curing when a large amount of an organic solvent is used.

The amount of an organic solvent and the amount of a reactive diluent may be appropriately adjusted depending on the thickness of a reflective layer and the coating methods such as printing and application etc.

A liquid, or greasy or plastic raw material composition in which the ultraviolet reflective filler particles are contained in the raw material composition of the ultraviolet reflective material may contain a small amount of a crosslinking agent facilitating three-dimensional crosslinking into a silicone resin, for example, a crosslinking agent such as hydrogen organopolysiloxane as described above and platinum group metal catalyst-containing polysiloxane, and peroxide as long as the effects of the present invention are not interfered.

The raw material composition of such an ultraviolet reflective material may also be used as a resist. This composition, which is for example a heat curing resist, will cure upon heating, for example, at 100° C. or above.

When it is of a condensation reaction type thereof, a crosslinking agent, a catalyst, a reaction inhibitor, a reinforcing agent, and various other additives depending on the applications may be blended in this raw material composition in addition to the main ingredients.

This raw material composition may contain an adhesion-conferring component as an adhesive component. Adhesion-conferring components include and silane compounds and siloxane compounds having a reactive functional group such as vinyl groups, phenyl groups, alkoxy groups, epoxy ring-containing groups such as 2,3-epoxypropyl groups (C₂H₃O—), (meth)acryloyl groups. Such adhesion-conferring components include, specifically, CH₂═CHSi(OCH₃)₃, C₆H₅Si(OCH₃)₃, CH₂═CHSi(OCH₂H₄OCH₃)₃, C₂H₃O—CH₂O(CH₂)₃Si(OCH₃)₃, C₂H₃O—CH₂O(CH₂)₃SiCH₃(OCH₃)₂, CH₂═CH—CO—O(CH₂)₃SiCH₃(OCH₃)₂, CH₂═CCH₃—CO—O(CH₂)₃SiCH₃(OCH₃)₂, 2-(2,3-epoxypropyloxypropyl)-2,4,6,8-tetramethyl-cyclotetrasiloxane, 2-(2,3-epoxypropyloxypropyl)-2,4,6,8-tetramethyl-6-(trimethoxysilylethyl)cyclotetrasiloxane, and the like.

The ultraviolet reflective filler particles such as alumina etc. have lower reflectance in the visible light region than titanium dioxide, but they are also extremely reflective in the ultraviolet region, especially at the wavelength region of 200 to 315 nm in the short-wavelength ultraviolet region and the mid-wavelength ultraviolet region. Moreover, it has high thermal conductivity and excellent heat dissipation.

Therefore, reflectivity and heat dissipation can be achieved by using a silicone resin and appropriately selected ultraviolet reflective filler particles, and thus the ultraviolet reflective materials 10 and 20 can be configured for the intended use by including alumina, magnesium hydroxide, and/or silicon oxide that can improve reflectivity as ultraviolet reflective filler particles in order to modulate reflectivity and heat radiation.

The ultraviolet reflective layers 17a and 17b of the ultraviolet reflective materials 10 and 20 are to be heat cured by a condensation reaction in the absence of a solvent or preferably in the presence of a solvent using a liquid, or greasy or plastic raw material composition in which the condensation-curable silicone resin raw material, the ultraviolet reflective filler particles 12a and 12b, and if necessary, a silane coupling agent. The liquid, or greasy or plastic composition as described above may be applied with a coater while adjusting so as to provide an appropriate thickness of 1 to 2000 μm. In the case of a chip-on-board where electronic circuits are formed by combining chips and devices, this raw material composition may be applied by screen printing or other methods, leaving the area where the chips are mounted.

Silane coupling agents include those having an alkyloxy group, a vinyl group, an amino group, and/or an epoxy group as reactive functional groups. A coupling agent such as titanate and aluminate may be used other than a silane coupling agent. When a silane coupling agent is included in the composition, the resulting silicone resin has significantly enhanced strength as compound with those without the silane coupling agent. This is because the silicone resin firmly incorporates the ultraviolet reflective filler particles, for example anatase-type titanium dioxide into the mesh structure. In particular, the ultraviolet reflective layers 17a and 17b of the ultraviolet reflective materials 10 and 20 containing ultraviolet reflective filler particles treated with a silane coupling agent has improved bending strength, wettability, and dispersion, and are thus of high quality. This is because the ultraviolet reflective filler particles are crosslinked to silicone via a silane coupling agent. The silane coupling treatment as described above includes, for example, adding 1 mass % of a silane coupling agent to anatase-type titanium dioxide, performing surface treatment by stirring with a Henschel mixer, and drying at 100 to 130° C. for 30 to 90 minutes.

In these ultraviolet reflective materials, the surfaces thereof themselves are roughened or unevened in the order of nanometers to micrometers order by surface treatment such as physical polishing/roughening or chemical etching to facilitate diffused reflection. In addition, the ultraviolet reflective filler particles, which is reflective in nature, are exposed to further improve the reflection efficiency as much as about several percent. In such surface-treated ultraviolet reflective materials, the surfaces of the exposed ultraviolet reflective filler particles are subjected to silane coupling treatment to facilitate adhesion to metal. Therefore, a metal film such as metal plating etc. can easily be applied even on a surface of an adhesion-resistant condensation-cured silicone resin by virtue of the anchor effect resulting from surface roughness and improved chemical bonding resulting from silane coupling. Moreover, the strength of the reflecting layer itself is also improved. Furthermore, surface roughening can prevent adhesion of fine matter and foreign objects, and facilitate removal of fine matter and foreign objects.

The ultraviolet reflective material as described above can have an electrically conductive pattern. When the ultraviolet reflective layer covering a support having an electrically conductive pattern or a wiring (circuit) board is polished to expose the electrically conductive pattern, or the ultraviolet reflective layer only partially covers the support having an electrically conductive pattern, all parts of the support or the wiring board except for the region having electrically conductive pattern can serve as a reflective layer. Therefore, the reflection efficiency is extremely high at 200 to 1000 nm including ultraviolet radiation, visible light, and near-infrared radiation, particularly in 200 to 315 nm, i.e., in the ultraviolet short-wavelength ultraviolet region and the mid-wavelength ultraviolet region where reflectance could not be obtained conventionally. Polishing may be mirror polishing, surface-roughing polishing, or cutting and grinding.

In polishing, specifically, the ultraviolet reflective filler particles are exposed on the surface of the condensation-cured silicone resin by rubbing with coated abrasive having a roughness of No. 500 to 1000, for example, sandpaper; by polishing with a fine particle-containing abrading agent; by performing honing with a grinding stone; by performing buffing by rubbing with a soft material such as cloth skin etc.; or by contacting a high speed roller having an emboss-treated surface of sandpaper-like unevenness; and the like. In surface roughening, specifically, physical surface processing is performed until the ultraviolet reflective filler particles are exposed on the surface of the condensation-cured silicone resin by performing sandblast treatment or pearskin treatment by blowing coarse metal grains, sand, or abrasives; by performing wet blast treatment by spraying an abrasive-suspended liquid; by scratching with a metal brush etc., a metal scrub brush, or steel wool; or by removing organic matter by cleaning treatment with ultraviolet irradiation or corona discharge treatment; and the like. In chemical etching, specifically, chemical surface processing is performed until the ultraviolet reflective filler particles are exposed on the surface of the condensation-cured silicone resin by performing acid treatment with strong acid such as hydrochloric acid, sulfuric acid, nitric acid, and hydrofluoric acid; or by performing alkali treatment with caustic soda, and the like. In the case of surface-roughening by polishing the ultraviolet reflective layers 17a and 17b, the material preferably has a hardness of 60 or more as measured with a JIS A hardness meter in accordance with JIS K 6253 in order to facilitate polishing.

Light reflection is enabled on the surface of the ultraviolet reflective filler particles exposed by polishing, roughening, or chemical etching as described above, further improving reflection efficiency. Physical polishing is more preferred

The ultraviolet reflective layers 17a and 17b of the ultraviolet reflective materials 10 and 20 subjected to surface roughening can facilitate adhesion to metal, and also facilitate robust adhesion of a metal film on the surface of the corresponding condensation-cured silicone resin. The ultraviolet reflective layers 17a and 17b of the ultraviolet reflective materials 10 and 20 including the ultraviolet reflective filler particles subjected to coupling treatment can facilitate adhesion to metal, and also facilitate robust adhesion of a metal film on the surface of the corresponding condensation-cured silicone resin. Metal films include plated coatings of copper, silver, gold, nickel, palladium, and the like; vapor-deposited metal films; adhesives; and metal foils bonded by metal spraying. Alternatively, the metal film may be a two-layer metal film having different types of metal films, for example, a two-layer metal film where gold is plated on copper.

A metal film is typically difficult to be applied on condensation-cured silicone resins which are adhesion-resistant in nature. However, the present ultraviolet reflective layers 17a and 17b of the ultraviolet reflective materials 10 and 20 can provide good adhesion to a metal film.

A metal film may be formed directly on the ultraviolet reflective material 10 and 20 by plating, metal deposition, or bonding a metal foil with an adhesive. The ultraviolet reflective layers 17a and 17b of the ultraviolet reflective materials 10 and 20 may be pre-primed by corona treatment, plasma treatment, ultraviolet treatment, flame treatment, Itro treatment, or by coating with polyparaxylylene, and then coated with a metal film thereon.

An example of a method of forming a metal film is as follows. A film is attached as a masking material to the ultraviolet reflective layers 17a and 17b of the ultraviolet reflective materials 10 and 20 containing the ultraviolet reflective filler particles which are formed in a plate shape. Next, in order to provide a coating of “Parylene C” (Product name from Nippon parylene LLC; “Parylene” is a registered trademark; —[(CH₂)—C₆H₃Cl—(CH₂)]ₙ—) as polyparylene, powdered monochloroparaxylene dimers, which are the raw material dimer of “Parylene C,” are placed in a vaporization chamber and heated under reduced pressure, and the evaporated dimers is directed into a thermal decomposition chamber to form highly reactive paraxilylene monomer radicals, which are then deposited on a reflective substrate to form a coating of polyparaxilylenes with a thickness of 0.5 to 5 microns, preferably 1 to 2 microns, thereby preparing a primer layer. On top of the primer layer, a silver layer with a thickness of several microns is formed as a metal layer by vacuum evaporation. The masking material is then peeled off to obtain the ultraviolet reflective materials 10 and 20 having a metal film attached which has low gas permeability and insulation resistance.

A plating method comprises: first surface roughening with acid or alkali the ultraviolet reflective layers 17a and 17b of the ultraviolet reflective materials 10 and 20 containing the ultraviolet reflective filler particles and formed in a plate shape; and then performing nickel plating by electroless nickel plating; and then performing copper plating by electrolytic plating. Gold or silver plating may be further performed depending on the applications.

A method of attaching a copper foil comprises: forming an adhesive layer on the back of the copper foil; attaching that side of the adhesive layer to the ultraviolet reflective material 20 which containing the ultraviolet reflective filler particles and formed in a plate shape; and then performing heat curing with a hydraulic press to achieve crosslinking adhesion. The copper foil may be a rolled continuous sheet or a separate sheet obtained by cutting the rolled continuous sheet. The adhesive layer may be provided on the side of the ultraviolet reflective material 20. The rolled copper foil in a wound state may be withdrawn, and attached to the ultraviolet reflective material 20, and then rolled up again.

When a metal layer is provided on the support 16, and a circuit is formed on the metal layer by etching, and the raw material composition of the ultraviolet reflective material is applied by screen printing thereon to form the ultraviolet reflective layers 17a and 17b of the ultraviolet reflective materials 10 and 20 except for portions where a light-emitting diode chip is wired and mounted, a gas barrier layer may be provided between the circuit and the ultraviolet reflective layers 17a and 17b. The ultraviolet reflective layers 17a and 17b of the ultraviolet reflective materials 10 and 20 are composed of a three-dimensionally crosslinked condensation-cured silicone resin and ultraviolet reflective filler particles, and are more gas permeable than common resins such as epoxy resin etc. Therefore, the metal layer of the circuit may be corroded to form an oxide film, resulting in detachment between the ultraviolet reflective layers 17a and 17b and the metal layer. To prevent this, a coating having gas barrier properties may be formed between the ultraviolet reflective layers 17a and 17b and the metal layer. The gas barrier layer may be flexible or non-flexible. The gas barrier layer preferably has a thickness of 1 to 30 μm. As a material for the gas barrier layer, resins having lower gas permeability than the condensation-cured silicone resins can be appropriately selected, including photoresists such as epoxy resin etc., paraxylene coating, polyimide resin, polyparaxylenes, urethane resin, acrylic resin, and polyamide.

The condensation-cured silicone resins are highly gas permeable, and allow corrosive gases to permeate easily, and thus may cause corrosion of the metal layer. To prevent this, it is preferred that a coating of a gas barrier resin is applied as a gas barrier layer, and the ultraviolet reflective layers 17a and 17b of the ultraviolet reflective materials 10 and 20 is then provided on the coating.

A metal foil or a metal plating may be attached on the ultraviolet reflective layers 17a and 17b of the ultraviolet reflective materials 10 and 20. A pattern may be formed by applying the raw material composition of the ultraviolet reflective material on a copper foil, and then attaching the copper foil to a substrate, and then performing etching, or a silicone resin may be applied on a substrate, and then plating may be performed.

The ultraviolet reflective materials 10 and 20 are non-adhesive because the ultraviolet reflective layers 17a and 17b are composed of a condensation-cured silicone resin. Therefore, when fine matter or foreign objects such as dust and dirt adhere to the ultraviolet reflective materials 10 and 20, they will not stick to the ultraviolet reflective materials 10 and 20. An adhesive roller may be used to easily wipe fine matter or foreign objects off from the ultraviolet reflective materials 10 and 20. The ultraviolet reflective materials 10 and 20 are non-adhesive, but highly electrically insulating. Therefore, fine matter or foreign objects such as dirt and dust tend to be attracted due to static electricity. Accordingly, the adhesion of such fine matter or foreign objects can be prevented by coating the reflective surfaces of the ultraviolet reflective materials 10 and 20 with a silicone hard coat layer. Even if fine matter or foreign objects adhere, they can be easily removed by blowing air. Silicone hard coating agents that can be used for the ultraviolet reflective materials 10 and 20 include silicone hard coating agents in which silica or fluorine powder is dispersed; and silicone coating agents used for surface treatment of air bags.

Next, referring to FIG. 1, we will specifically describe a lighting fixture as an exemplary luminescent device in which a package case 10 serving as the present ultraviolet reflective material and the ultraviolet reflective material 20 having the ultraviolet reflective layers 17a and 17b contain a condensation-cured silicone resin including the M units, the D units, and the T units in the main chain as the main ingredients; and alumina as an example of the ultraviolet reflective filler particles.

The ultraviolet reflective layers 17a and 17b of the ultraviolet reflective material 20 that forms a part of a wiring board are formed of a condensation-cured silicone resin containing alumina particles 12b. Some of the alumina particles 12b is exposed from the surface in the attachment side to the light-emitting diode 13 present on the ultraviolet reflective material 20. Copper films 15a and 15b, which are electrically conductive metal films, are attached on that surface of the ultraviolet reflective material 20 to form an electrically conductive pattern that leads to a power supply (not shown). Two lead wires 14a and 14b extending from the light-emitting diode 13 are connected to the corresponding copper films 15a and 15b, respectively. The condensation-cured silicone resin is exposed in regions other than the electrically conductive pattern on the surface of the ultraviolet reflective material 20, where some of the alumina particles 12b are exposed, and the color is while, and excellent opacity is achieved so that no light leaks out. In addition, light in an ultraviolet wavelength range of 200 to 400 nm, particularly in 200 to 315 nm, i.e., in the short-wavelength ultraviolet region of and the mid-wavelength ultraviolet region, which is difficult to be reflected by a conventional ultraviolet reflective layer, can be reflected by that region with extremely high reflectance. Furthermore, light of longer wavelengths in the visible light region and a heat ray such as infrared light of longer wavelengths can also be reflected with good reflectance.

The package case 10 is also formed of the raw material composition of a condensation-cured silicone resin containing the same type of alumina particles 12a. The package case 10 wraps around the light-emitting diode 13, and is widen toward the opened end in the emitting direction along a sloped inner wall 11, and is integrally bonded via an adhesive layer (not shown) to the surface of the attachment side of the light-emitting diode 13 present on the ultraviolet reflective material 20 of a wiring board. By virtue of the alumina particles 12a, this package case body 10 is also white in color, and has excellent opacity so that no light leaks, and can reflect, with an extremely high reflectance, ultraviolet radiation in an ultraviolet wavelength range of 200 to 400 nm, particularly 200 to 315 nm, i.e., the short-wavelength ultraviolet region and the mid-wavelength ultraviolet region, which is difficult to reflect with a conventional ultraviolet reflective layer. Furthermore, light of longer wavelengths in the visible light region and a heat ray such as infrared light of longer wavelengths can also be reflected with good reflectance.

Both the ultraviolet reflective material 20 having the ultraviolet reflective layer 17a and the ultraviolet reflective material as the package case 10 are chemically stable and discoloration resistant, and contain the M unit, the D unit, and the T unit in the main chain as the main ingredients, and the ultraviolet reflective layers 17a and 17b are formed of a three dimensionally crosslinked condensation-cured silicone resin. Therefore, they show high reflectance in an ultraviolet wavelength range of 200 to 400 nm, particularly 200 to 315 nm, i.e., in the short-wavelength ultraviolet region and the mid-wavelength ultraviolet region, and can maintain the initial white color without discoloration even after long-term exposure to ultraviolet radiation or high-intensity light, and further has high mechanical strength, excellent light resistance, heat resistance, and weathering resistance, leading to excellent durability.

In the lighting fixture 1, the surface of the non-attachment side of the light-emitting diode 13 present on the ultraviolet reflective layer 17a of the ultraviolet reflective material 20 is attached to the support 16. A lighting fixture may be used comprising multiple pairs of the ultraviolet reflective material 20 having the light-emitting diode 13 mounted and the package case 10 arranged in an orderly fashion in all directions. The opening of the package case 10 in the side of the emitting direction may be covered with a transparent plate or film made of glass or a resin. The transparent plate or film may contain pigments, dyes, fluorescent agents, or phosphorescent agents that can convert the wavelength of light transmitted through it to the desired wavelength. The opening of the package case 10 in the side of the emitting direction may be covered with a lens such as a convex, concave, or Fresnel lens (not shown).

The ultraviolet reflective layer 17a of the ultraviolet reflective material 20 may be formed on the support 16 by various printing methods such as screen printing; spraying; brushing; and coating processes such as application etc.

The support 16 as described above may be in any three-dimensional shape etc. such as a non-deformable hard or rigid film shape, a plate shape, a cylindrical shape such as a circular cylinder, a spherical shape, and a bowl-like shape etc.; a flexible and pliable soft sheet such as the so-called flexible printed circuit (FPC) or a hard sheet that is flexible enough to be biased upon bent; a roll that can be rolled up; or a very small working chip that can be built into various devices and does not take up much space. The support may be electrically conductive or thermally conductive/dissipative. A reflective layer may be provided on the front side, and, if necessary, a gluing/adhesive layer may be provided on the back side. The support 16 may also have an insulating layer formed on thereon.

The support 16 may be of either organic or inorganic materials. For example, mentioned are silicone resins, for example, organic materials such as condensation-cured/addition-cured or peroxide-cured silicone hard resins or hard resins or rubbers, imide resins, bismaleimide triazine resins, glass fiber-containing epoxy resins containing (Glass Epoxy), paper phenolic resins, Bakelite, polyethylene terephthalate resins, polybutylene terephthalate resins, polyacrylonitrile resins, polycarbonate resins for plastic films, fluororesins, polyimide resins, polyphenylene sulfide resins, aramid resins, polyetherether resins, polyetherimide resins, liquid crystal polymers, polyethersulfone resin, and cycloolefin resins; those formed using alumina, aluminum, copper, or nickel etc. as raw materials; aluminum foil, copper foil, nickel foil, aluminum sheet, copper sheet, and nickel sheet etc., but not limited to these. The ultraviolet reflective material 20 that forms a part of a wiring board contains an expensive condensation-cured silicone resin containing the M unit, the D unit, and T unit as the main repeating units, but can show sufficient reflection effects even when thinly applied on an inexpensive support 16, leading to reduction in production costs.

In that case, the ultraviolet reflective layers 17a and 17b of the ultraviolet reflective material 20 in a film-like shape is preferably provided on the support 16 as a film having a thickness of 10 to 200 μm by applying the raw material composition of that ultraviolet reflective material.

The package case 10 and a wiring board having the ultraviolet reflective material 20 are used as follows. The light-emitting diode 13 emits light when applying voltage to the light-emitting diode 13 through a cathode side copper film 15a and a lead wire 14a and an anode side copper film 15b and a lead wire 14b. A portion of the emitted light is directly irradiated to the outside through the opening in the side of the emitting direction of the package case 10. Another portion of the emitted light is reflected by the inner wall 11 of the package case 10, or by a region of the ultraviolet reflective material 20 other than the electrically conductive pattern on the surface of the wiring board, and is irradiated to the outside through the opening in the side of the emitting direction.

The ultraviolet reflective materials 10 and 20 are described with reference to those having a single-layer structure including the ultraviolet reflective layers 17a and 17b containing a silicone resin and the ultraviolet reflective filler particles 12a and 12b, but they may have a laminated structure. For example, the ultraviolet reflective filler particles 12a and 12b included in the ultraviolet reflective layers 17a and 17b which are each of single layer may include different types of particles, for example, ultraviolet reflective filler particles such as alumina etc. and inorganic powder other than those ultraviolet reflective filler particles, or the ultraviolet reflective layers 17a and 17b each may have a structure where two or more layers are laminated, and, for example, the types of the ultraviolet reflective filler particles such as alumina etc. and inorganic powder other than those ultraviolet reflective filler particles are different between a first layer and a second layer.

The ultraviolet reflective layers 17a and 17b which are each laminated may have different contents of ultraviolet reflective filler particles such as alumina etc. and inorganic powder other than those ultraviolet reflective filler particles contained in the ultraviolet reflective filler particles 12a and 12b that are dispersed in the condensation-cured silicone resin in each layer. For example, a laminated body is preferred in which a second reflective layer are laminated on a first reflective layer. The first reflective layer containing a condensation-cured silicone resin and alumina as the main ingredient of the ultraviolet reflective filler particles 12a and 12b, and the second reflective layer containing a condensation-cured silicone resin and an inorganic powder other than alumina as the main ingredients of the ultraviolet reflective filler particles 12a and 12b. The laminated body is not limited to those of two layers, but may be those of multiple layers. Rather than a single layer, the protective performance for the support is further enhanced by adding an additional layer below the ultraviolet reflective layer, the additional layer absorbing the transmitted ultraviolet radiation to protect the support.

In another aspect, the ultraviolet reflective materials 10 and 20 are included in another lighting fixture as shown in FIG. 2. A wiring board 21 is formed of a silicone resin containing an ultraviolet reflective filler particles 12c such as alumina so that a glass cloth 22 is included therein. On the surface of the wiring board 21, electrically conductive patterns of copper films 15a and 15b as electrically conductive metal films are formed, and the lead wires 14a and 14b for the light-emitting diode 13 are connected to the corresponding copper films 15a and 15b, respectively. Furthermore, the electrically conductive patterns may be covered with an ultraviolet reflective layer 17a, except for the connection area of the light emitting diode 13 (not shown). The ultraviolet reflective layers 17a and 17b may have electrically conductive patterns formed on their front surfaces or on their back surfaces.

The ultraviolet reflective materials 10 and 20 may be used to reflect light from light sources including ultraviolet radiation other than UV-LEDs. They may be used to reflect light from light sources in near-infrared emitting devices. They may also be used in various luminescent devices, including lighting fixtures such as electric lamps having common incandescent lamps, halogen lamps, LEDs, and the like. Furthermore, they may be used to reflect light as in solar cells. Moreover, they may be attached to walls and fixtures near heat sources such as electric stoves and combustion stoves etc. to reflect infrared radiation to improve heating efficiency or to protect the walls and fixtures against heat.

### EXAMPLES

Examples of the present invention will be described in detail below, but the scope of the invention is not limited to these Examples.

Examples 1A to 1F which ultraviolet reflective protective base materials made of the silicone resins according to the present invention were produced and Comparative Examples 1a to 1c are shown below in.

### Example 1A

The followings were mixed in a ceramic three-roll mill to obtain a liquid A: 25 parts by mass of a methyl-based resin of KR-220LP (Product name from Shin-Etsu Chemical Co., Ltd.), which is an organopolysiloxane, as base resin; 11 parts by mass of diol of X-21-5841 (Product name from Shin-Etsu Chemical Co., Ltd.), which is polydimethylsiloxane diol, as a diol having hydroxy group at the both ends; 18 parts by mass of dipropylene glycol of DPG (Product name from FUJIFILM Wako Pure Chemical Corporation) as a solvent; 1 part by mass of AEROSIL R974 (Product name from Nippon Aerosil Co., Ltd.), which is dry silica having an average particle diameter of 12 μm, as a thickening agent; and polyhedron spherical alumina of AA-05 (Product name from Sumitomo Chemical Co., Ltd.) as ultraviolet reflective filler particles.

Next, the followings were mixed in a ceramic three-roll mill to obtain a liquid B: 5 parts by mass of an alkoxy silane compound KR-500 as a condensation-curable silicone resin raw material and 9 parts by mass of an alkoxy silane compound of X-40-9250 (both are Product names from Shin-Etsu Chemical Co., Ltd.); and 3 parts by mass of a thickening agent of AEROSIL R974 (Product name from Nippon Aerosil Co., Ltd.) which is dry silica having an average particle diameter of 12 μm.

Further, 5 parts by mass of KBM-303 (Product name from Shin-Etsu Chemical Co., Ltd.) as a silane coupling agent, 0.4 parts by mass of CR15 (Product name from Momentive Performance Materials LCC) as tin-based catalyst SCA were mixed in a magnetic stirrer to obtain a liquid C.

The liquid A, the liquid B, and the liquid C were stirred in a defoaming mixer to obtain a raw-material composition of an ultraviolet reflective material. The raw-material composition of an ultraviolet reflective material was applied to an aluminum plate from Hakudo Corporation, and allowed to cure after screen printing to obtain an ultraviolet reflective material having an ultraviolet reflective layer with a thickness of 32 μm as a test piece in Example 1A.

### Test Example 1: Reflectance Measurement Tests

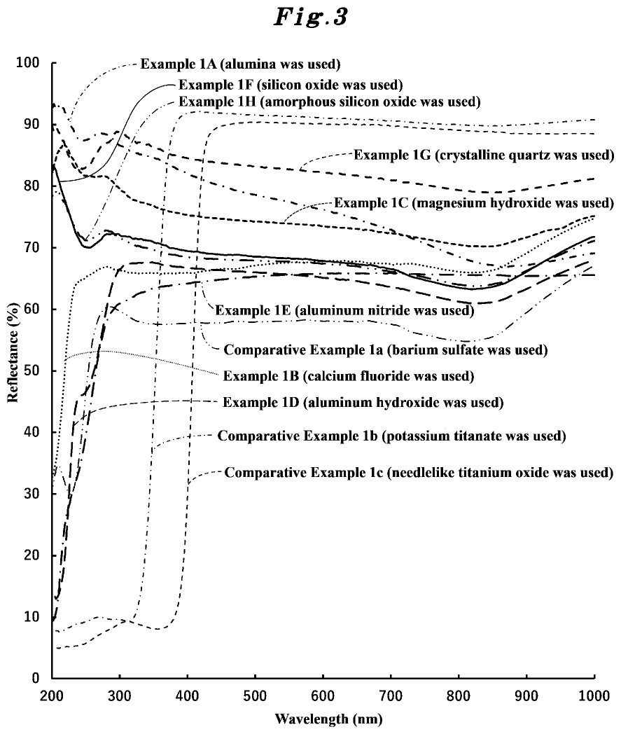

The test pieces of the ultraviolet reflective materials obtained in Example 1a were measured for reflectance at 200 to 1000 nm with a UV-VIS-NIR spectrometer UV-3600 (Product name from Shimadzu Corporation). Results are shown in FIG. 3.

### Examples 1B to 1H

Ultraviolet reflective materials having predetermined thickness were obtained as test pieces in Examples 1B to 1F as same as in Example 1A except that each of the components in Example 1 was changed in terms of types and amounts as shown in Tables 1-1 and 1-2. They were subjected to the same measurement test as the reflectance measurement test in Test Example 1. Results are summarized in FIG. 3.

Note that the followings were used as ultraviolet reflective filler particles in Examples 1B to 1H, respectively: Kisma 5A (Product name from Kyowa Chemical Industry Co., Ltd.) as magnesium hydroxide, calcium fluoride (from FUJIFILM Wako Pure Chemical Industries, Ltd.), B103 (Product name from Nippon Light Metal Co., Ltd.) as aluminum hydroxide, high purity aluminum nitride powder (Product name from Tokuyama Corporation) as aluminum nitride, SFP-20M (Product name from Denka Company Limited) as silicon oxide, silicon oxide as crystalline quartz RAC-1000 (content 99.8% by mass: crushed: average particle diameter 1 μm) (Product name of Tatsumori Ltd), amorphous silicon oxide (content 99.8% by mass: crushed: average particle diameter 2.5 μm).

### Comparative Examples 1a to 1c

Ultraviolet reflective materials having predetermined thickness were obtained as test pieces in Comparative Examples 1a to 1c as same as in Example 1A except that each of the components in Example 1 was changed in terms of types and amounts as shown in Tables 1-3. They were subjected to the same measurement test as the reflectance measurement test in Test Example 1. Results are summarized in FIG. 3.

Note that the followings were used as ultraviolet reflective filler particles in Comparative Examples 1a to 1c, respectively: precipitated barium sulphate 300 (from Sakai Chemical Industry Co., Ltd.), potassium titanate of TISMO N (Product name from Otsuka Chemical Co., Ltd.), PFR404 (Product name from Ishihara Sangyo Kaisha, Ltd.) which is needlelike titanium oxide having a long axis of 4 μm.

TABLE 1-1

| | | Example | | | Example | | | Example | | | Example | | |
|---|---|---|---|---|---|---|---|---|---|---|---|---|---|
| | | 1A | | | 1B | | | 1C | | | 1D | | |
| Types of liquid A/liquid B/liquid C | | A | B | C | A | B | C | A | B | C | A | B | C |
| Base resin | KR-220LP | 25 | | | 25 | | | 25 | | | 25 | | |
| | (methyl-based resin) | | | | | | | | | | | | |
| | X-21-5841 (both ends, | 11 | | | 11 | | | 11 | | | 11 | | |
| | silanol silicone oil) | | | | | | | | | | | | |
| Solvent | DPG | 18 | | | 30 | | | 48 | | | 22 | | |
| Condensation-curable | KR-500 | | 5 | | | 5 | | | 5 | | | 5 | |
| silicone | (alkoxy-based) | | | | | | | | | | | | |
| Resin raw material | X-40-9250 | | 9 | | | 9 | | | 9 | | | 9 | |
| | (alkoxy-based) | | | | | | | | | | | | |
| Thickening agent | AEROSIL R974 (dry | 1 | 3 | | 1 | 3 | | 1 | 3 | | 1 | 3 | |
| | silica) | | | | | | | | | | | | |
| Silane coupling | KBM-303 (silane | | | 5 | | | 5 | | | 5 | | | 5 |
| agent | coupling agent) | | | | | | | | | | | | |
| Catalyst | CR15 (tin-based | | | 0.4 | | | 0.4 | | | 0.4 | | | 0.4 |
| | catalyst: SCA) | | | | | | | | | | | | |
| Ultraviolet | AA-05 (polyhedron | 105 | | | | | | | | | | | |
| reflective filler | spherical alumina) | | | | | | | | | | | | |
| particles | Kisma 5A | | | | 105 | | | | | | | | |
| | (magnesium | | | | | | | | | | | | |
| | hydroxide) | | | | | | | | | | | | |
| | Calcium fluoride | | | | | | | 105 | | | | | |
| | B103 (aluminum | | | | | | | | | | 105 | | |
| | hydroxide) | | | | | | | | | | | | |
| | Aluminum nitride | | | | | | | | | | | | |
| | SFP-20M (silicon | | | | | | | | | | | | |
| | oxide) | | | | | | | | | | | | |
| | RAC-1000 (crystalline | | | | | | | | | | | | |
| | quartz) | | | | | | | | | | | | |
| | F05-12 (amorphous | | | | | | | | | | | | |
| | silicon oxide) | | | | | | | | | | | | |

| | | | | | | | | | | | | |
|---|---|---|---|---|---|---|---|---|---|---|---|---|
| Subtotal of components of each liquid of | 160 | 17 | 5.4 | 172 | 17 | 5.4 | 190 | 17 | 5.4 | 164 | 17 | 5.4 |

| liquid A/liquid B/liquid C | | | | |
|---|---|---|---|---|
| Sum total of components of whole liquid of | 182.4 | 194.4 | 212.4 | 186.4 |
| liquid A/liquid B/liquid C | | | | |
| Thickness of ultraviolet reflective layer (μm) | 32 | 31 | 39 | 35 |
| Refractive index of filler particles | about 1.76 | about 1.57 | about 1.43 | about 1.56 |

TABLE 1-2

| | | Example | | | Example | | | Example | | | Example | | |
|---|---|---|---|---|---|---|---|---|---|---|---|---|---|
| | | 1E | | | 1F | | | 1G | | | 1H | | |
| Types of liquid A/liquid B/liquid C | | A | B | C | A | B | C | A | B | C | A | B | C |
| Base resin | KR-220LP | 25 | | | 25 | | | 25 | | | 25 | | |
| | (methyl-based resin) | | | | | | | | | | | | |
| | X-21-5841 (both ends, | 11 | | | 11 | | | 11 | | | 11 | | |
| | silanol silicone oil) | | | | | | | | | | | | |
| Solvent | DPG | 28 | | | 24 | | | 58 | | | 36 | | |
| Condensation-curable | KR-500 (alkoxy-based) | | 5 | | | 5 | | | 5 | | | 5 | |
| silicone | | | | | | | | | | | | | |
| Resin raw material | X-40-9250 | | 9 | | | 9 | | | 9 | | | 9 | |
| | (alkoxy-based) | | | | | | | | | | | | |
| Thickening agent | AEROSIL R974 (dry | 1 | 3 | | 1 | 3 | | 1 | 3 | | 1 | 3 | |
| | silica) | | | | | | | | | | | | |
| Silane coupling | KBM-303 (silane | | | 5 | | | 5 | | | 5 | | | 5 |
| agent | coupling agent) | | | | | | | | | | | | |
| Catalyst | CR15 (tin-based catalyst: | | | 0.4 | | | 0.4 | | | 0.4 | | | 0.4 |
| | SCA) | | | | | | | | | | | | |
| Ultraviolet | AA-05 (polyhedron | | | | | | | | | | | | |
| reflective filler | spherical alumina) | | | | | | | | | | | | |
| particles | Kisma 5A (magnesium | | | | | | | | | | | | |
| | hydroxide) | | | | | | | | | | | | |
| | Calcium fluoride | | | | | | | | | | | | |
| | B103 (aluminum | | | | | | | | | | | | |
| | hydroxide) | | | | | | | | | | | | |
| | Aluminum nitride | 105 | | | | | | | | | | | |
| | SFP-20M (silicon oxide) | | | | 105 | | | | | | | | |
| | RAC-1000 (crystalline | | | | | | | 105 | | | | | |
| | quartz) | | | | | | | | | | | | |
| | F05-12 (amorphous | | | | | | | | | | 105 | | |
| | silicon oxide) | | | | | | | | | | | | |

| | | | | | | | | | | | | |
|---|---|---|---|---|---|---|---|---|---|---|---|---|
| Subtotal of components of each liquid of | 170 | 17 | 5.4 | 166 | 17 | 5.4 | 190 | 17 | 5.4 | 164 | 17 | 5.4 |

| liquid A/liquid B/liquid C | | | | |
|---|---|---|---|---|
| Sum total of components of whole liquid of | 192.4 | 188.4 | 212.4 | 186.4 |
| liquid A/liquid B/liquid C | | | | |
| Thickness of ultraviolet reflective layer (μm) | 33 | 31 | 32 | 32 |
| Refractive index of filler particles | 1.9~2.2 | 1.44~1.5 | 1.44~1.5 | 1.44~1.5 |

TABLE 1-3

| | | Comparative | | | Comparative | | | Comparative | | |
|---|---|---|---|---|---|---|---|---|---|---|
| | | Example 1a | | | Example 1b | | | Example 1c | | |
| Types of liquid A/liquid B/liquid C | | A | B | C | A | B | C | A | B | C |
| Base resin | KR-220LP (methyl-based | 25 | | | 25 | | | 25 | | |
| | resin) | | | | | | | | | |
| | X-21-5841 (both ends, | 11 | | | 11 | | | 11 | | |
| | silanol silicone oil) | | | | | | | | | |
| Solvent | DPG | 18 | | | 260 | | | 18 | | |
| Condensation-curable | KR-500 (alkoxy-based) | | 5 | | | 5 | | | 5 | |
| silicone | | | | | | | | | | |
| Resin raw material | X-40-9250 (alkoxy-based) | | 9 | | | 9 | | | 9 | |
| Thickening agent | AEROSIL R974 (dry silica) | 1 | 3 | | 1 | 3 | | 1 | 3 | |
| Silane coupling | KBM-303 (silane coupling | | | 5 | | | 5 | | | 5 |
| agent | agent) | | | | | | | | | |
| Catalyst | CR15 (tin-based catalyst: | | | 0.4 | | | 0.4 | | | 0.4 |
| | SCA) | | | | | | | | | |
| Filler particles | Precipitated barium | 105 | | | | | | | | |
| | sulphate 300 | | | | | | | | | |
| | TISMO N (potassium | | | | 105 | | | | | |
| | titanate) | | | | | | | | | |
| | PFR404 (needlelike | | | | | | | 105 | | |
| | titanium oxide) | | | | | | | | | |

| | | | | | | | | | |
|---|---|---|---|---|---|---|---|---|---|
| Subtotal of components of each liquid of liquid A/ | 160 | 17 | 5.4 | 402 | 17 | 5.4 | 160 | 17 | 5.4 |

| liquid B/liquid C | | | |
|---|---|---|---|
| Sum total of components of liquid A/liquid B/ | 182.4 | 424.4 | 182.4 |
| liquid C | | | |
| Thickness of ultraviolet reflective layer (μm) | 23 | 40 | 31 |
| from whole liquid | | | |
| Refractive index of filler particles | about 1.64 | | |

As clearly shown in FIG. 3, the ultraviolet reflective materials from Examples 1A to 1F were capable of reflecting light in the entire ultraviolet region ranging from the short-wavelength ultraviolet region (UVC) to the long-wavelength ultraviolet region (UVA) with high reflectance when alumina, magnesium hydroxide, calcium fluoride, aluminum hydroxide, aluminum nitride, and silicon oxide were used as ultraviolet reflective filler particles. Effective reflectance was also obtained at wavelengths up to 1000 nm, including the visible light region. In particular, when alumina, magnesium hydroxide, and silicon oxide were used, light at wavelengths in the short-wavelength ultraviolet region and the mid-wavelength ultraviolet region such as 200 to 315 nm, which were conventionally difficult to be reflected, was able to be reflected with high reflectance. This is particularly significant in the short-wavelength ultraviolet region inclusive of 200 nm.

In contract, the ultraviolet reflective materials from Comparative Examples 1a to 1c showed high reflectance at 1000 nm or less and up to near the visible light region, but reflectance decreased rapidly at about 360 nm, 420 nm or less when potassium titanate or titanium dioxide were used as filler particles, and reflectance was relatively low across the entire region when barium sulfate was used as filler particles.

### Example 2 and Comparative Example 2

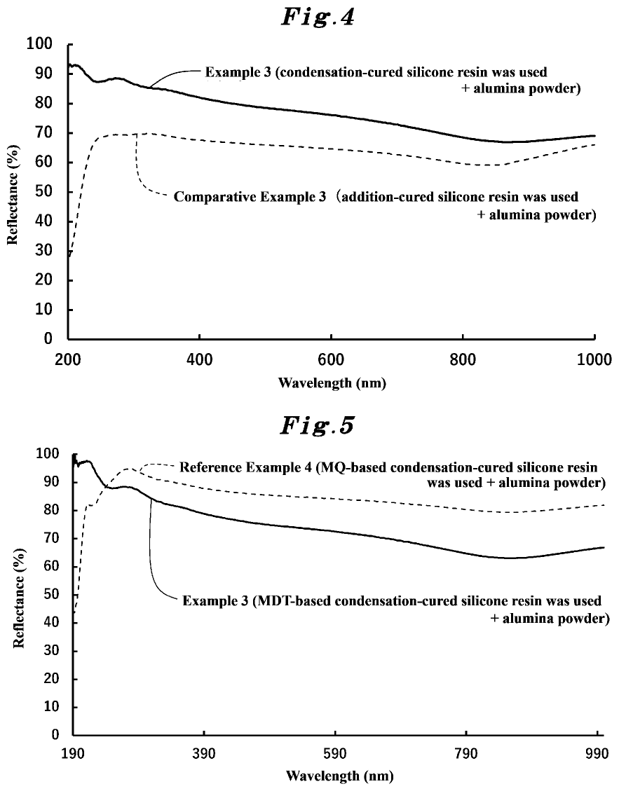

As shown in Table 2 below, the test pieces of the ultraviolet reflective materials in Example 3 were obtained as same as in Example 1. Meanwhile, in Comparative Example 2, test pieces of ultraviolet reflective materials were obtained as same as in Example 1 except that LUMISIL LR 7601/80 and LUMISIL LR 7601/80 (both are produced names from Asahi Kasei Wacker Silicones Corporation) were used as an addition-cured silicone resin raw materials instead of the condensation-curable silicone resin raw material used in Example 1. They were subjected to the same measurement test as the reflectance measurement test in Test Example 1. Results are summarized in FIG. 4.

TABLE 2

| | | | | | Comparative | | |
|---|---|---|---|---|---|---|---|
| | | Example 3 | | | Example 3 | | |
| Types of liquid A/liquid B/liquid C | | A | B | C | A | B | C |
| Base resin | KR-220LP (methyl system resin) | 25 | | | | | |
| | X-21-5841 (both ends, silanol | 11 | | | | | |
| | silicone oil) | | | | | | |
| Solvent | DPG | 18 | | | | | |
| Condensation-curable silicone | KR-500 (alkoxy-based) | | 5 | | | | |
| Resin raw material | X-40-9250 (alkoxy-based) | | 9 | | | | |
| addition-curable silicone resin | LUMISIL LR 7601/80A | | | | 50 | | |
| raw material | (addition type) | | | | | | |
| | LUMISIL LR 7601/80B | | | | | 50 | |
| | (addition type) | | | | | | |
| | YC9362 (addition type) | | | | | | 10 |
| Thickening agent | AEROSIL R974 (dry silica) | 1 | 3 | | | | |
| Silane coupling agent | KBM-303 (silane coupling agent) | | | 5 | | | |
| Catalyst | CR15 (tin-based catalyst: SCA) | | | 0.4 | | | |
| Ultraviolet reflective filler | AA-05 (polyhedron spherical | 105 | | | 50 | 50 | |
| particles | alumina) | | | | | | |

| | | | | | | |
|---|---|---|---|---|---|---|
| Subtotal of components of each liquid of liquid A/liquid B/ | 160 | 17 | 5.4 | 100 | 100 | 10 |

| liquid C | | |
|---|---|---|
| Sum total of components of whole liquid of liquid A/liquid B/ | 182.4 | 210 |
| liquid C | | |
| Thickness of ultraviolet reflective layer (μm) | 32 | 30 |
| Refractive index of filler particles | about 1.76 | about 1.76 |

As clearly shown in FIG. 4. it was observed that even if the same alumina was used as the ultraviolet reflective filler particles, the ultraviolet reflective materials having an ultraviolet reflective layer containing an addition-cured silicone resin in Comparative Example 3 had reflectance of less than 70% across the entire wavelength range of 200 to 1000 nm, and further had reflectance rapidly decreased in a wavelength range of about 200 to 240 nm. In contrast, it was observed that the ultraviolet reflective materials having an ultraviolet reflective layer containing a condensation-cured silicone resin from Example 3 had reflectance of approximately 70% or more across the entire wavelength range of 200 to 1000 nm, and were able to further maintain reflectance at 80% or more in a wavelength range of 200 to about 450 nm, and moreover the reflectance tended to increase at lower wavelengths. High ultraviolet reflectivity was obtained because the ultraviolet reflective layers contained a combination of a condensation-cured silicone resin and specific ultraviolet reflective filler particles such as alumina etc.

### Example 3 and Reference Example 4

As shown in Table 3 below, test pieces of ultraviolet reflective materials of Example 3 having an ultraviolet reflective layer with a thickness of 24 μm were obtained as same as in Example 1. In construct, in Reference Example 4, test pieces of ultraviolet reflective materials of Reference Example 4 were obtained as same as in Example 1 except that DOWSIL 2441RESIN (Product name from Dow and Toray Industries, Inc.) as a condensation-curable silicone resin raw material having the M unit and the Q unit was used instead of the condensation-curable silicone resin raw material of the MDT system having the M unit, the D unit, and the T unit from Example 1. They were subjected to the same measurement test as the reflectance measurement test in Test Example 1. Results are summarized in FIG. 5.

TABLE 3

| | | | | Reference | | |
|---|---|---|---|---|---|---|
| | Example 4 | | | Example 5 | | |
| Types of liquid A/liquid B/liquid C | A | B | C | A | B | C |

| | | | | | | |
|---|---|---|---|---|---|---|
| Base resin | KR-220LP (methyl system resin) | 25 | | | | |
| | X-21-5841 (both ends, silanol | 11 | | | | |
| | silicone oil) | | | | | |
| Solvent | DPG | 18 | | | | |
| | Hexane | | 15 | | 16 | |
| Condensation-curable silicone | KR-500 (alkoxy-based) | | 9 | | | |
| resin raw material(MDTblend) | X-40-9250 (alkoxy-based) | | | | | |
| Condensation-curable silicone | DOWSIL 2441RESIN | | | | 125 | |
| resin raw material(MQblend) | | | | | | |
| Thickening agent | AEROSIL R974 (dry silica) | 1 | 3 | | | |
| Silane coupling agent | KBM-303 (silane coupling agent) | | | 5 | | 5 |
| Catalyst | CR15 (tin-based catalyst: SCA) | | | 0.4 | | 0.4 |
| Ultraviolet reflective | AA-05 (polyhedron spherical | 105 | | | 105 | |
| filler particles | alumina) | | | | | |

| | | | | | | |
|---|---|---|---|---|---|---|
| Subtotal of components of each liquid of liquid A/liquid B/ | 160 | 17 | 5.4 | 246 | 0 | 5.4 |

| liquid C | | |
|---|---|---|
| Sum total of components of whole liquid of liquid A/liquid B/ | 182.4 | 251.4 |
| liquid C | | |
| Thickness of ultraviolet reflective layer (μm) | 24 | 25 |
| Refractive index of filler particles | about 1.76 | about 1.76 |

As clearly shown in FIG. 5. when the condensation-cured silicone resins and the same alumina as ultraviolet reflective filler particles were used, the reflectance was 94% for the condensation-cured silicone resin of the MQ system and 88% for the condensation-cured silicone resin of the MDT system at 280 nm, indicating that the MQ system showed higher reflectance. However, the reflectance was equal for the MQ and MDT systems at 240 nm. At shorter wavelengths than 240 nm, the reflectance was 57% for the MQ system and 97% for the MDT system at 200 nm; and the reflectance was 43% for the MQ system and 95% for the MDT system at 190 nm, indicating that the MQ system had lower reflectance while the MDT system had improved reflectance. That is, use of the MDT system was able to provide higher reflectance than the MQ system in the short-wavelength ultraviolet region of 190 to 240 nm, including 200 nm.

### Reference Examples 1 to 3

In Reference Example 1, a test piece was prepared in which a condensation-cured silicone resin was applied to an aluminum plate to form a 32 μm resin layer as in Example 1 except that the ultraviolet reflective filler particles were not used.

In Reference Example 2, a test piece was prepared in which an addition-cured silicone resin was applied to an aluminum plate to form a 28 μm resin layer as same as in Comparative Example 3 except that the ultraviolet reflective filler particles were not used.

In Reference Example 3, a bare aluminum plate was used as a test piece.

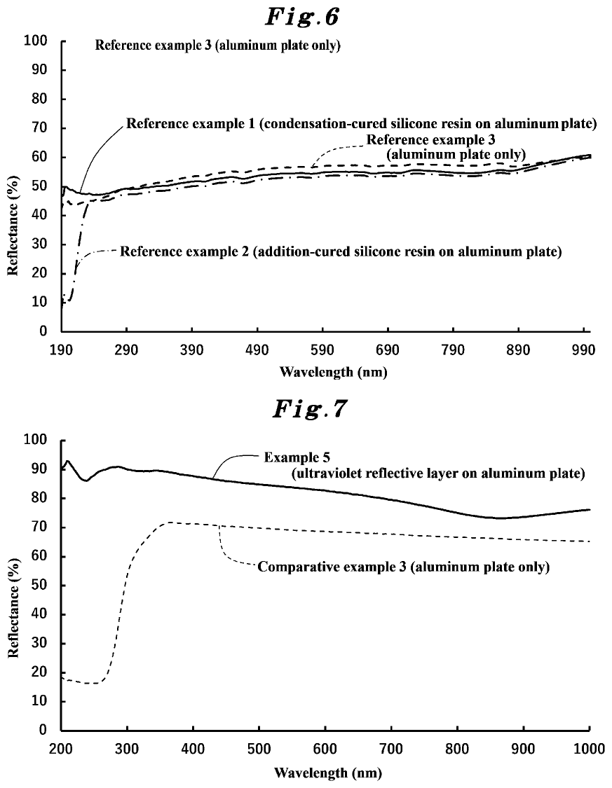

The test pieces from Reference Examples 1 to 3 were subjected to measurement tests as same as in the reflectance measurement tests in Test Example 1. Results are shown in FIG. 6.

As clearly shown in FIG. 6, the addition-cured silicone showed absorption in the ultraviolet region.

### Example 5 and Comparative Example 3

A test piece of an ultraviolet reflective material of Example 5 was obtained having a 24-μm thick layer on an alumina plate as same as in Example 1. On the other hand, a test piece of Comparative Example 3 consisted only of an alumina plate. The test pieces from Example 5 and Comparative Example 3 were subjected to measurement tests as in the reflectance measurement tests in Test Example 1. Results are shown in FIG. 7.

It was clear from FIG. 7 that the reflectance at 200 to 1000 nm, particularly in the ultraviolet region did not show much improvement when an alumina plate was used whereas the ultraviolet reflective material having an ultraviolet reflective layer containing ultraviolet reflective filler particles such as alumina powder showed a significant improvement in reflectance at 200 to 1000 nm, particularly in the ultraviolet region.

As clearly understood from these Examples, the ultraviolet reflective materials each having an ultraviolet reflective layer containing a condensation-cured silicone resin and ultraviolet reflective filler particles such as alumina etc. showed excellent reflectance of light in a wavelength range of 200 to 1000 nm, particularly in the ultraviolet region.

### INDUSTRIAL APPLICABILITY

The ultraviolet reflective material according to the present invention may be mounted on light-emitting devices such as light-emitting diodes that emit not only visible light but also ultraviolet radiation, particularly emit ultraviolet radiation; luminescent devices such as incandescent bulbs, halogen lamps, mercury lamps, and fluorescent lamps, and may be used in a wiring board and a package case and installed on light sources thereof to reflect the emitted light in a desired direction.

The method of producing an ultraviolet reflective material according to the present invention is useful to manufacture those luminescent devices.

The raw material composition of the ultraviolet reflective material according to the present invention is also useful for forming an ultraviolet reflective layer simply by applying, spraying, dipping, molding, and the like.

The raw material composition according to the present invention can be stored stably at room temperature, and thus can be supplied as a caned product for forming ultraviolet reflective layers of ultraviolet reflective materials. It is also useful to form an ultraviolet reflective layer by appropriately adjusting viscosity.

### EXPLANATIONS OF LETTERS OR NUMERALS

1: Luminescent Device, 2: Solar Cell Assembly, 10: Package Case as Ultraviolet Reflective Material, 11: Inner Wall, 12a/2B/12C: Ultraviolet Reflective filler particles, 13: Light-emitting Diode, 14a/14b: Lead, 15a/15b: Copper Film, 16: Support, 17a/17b: Ultraviolet Reflective Layer, 20: Ultraviolet Reflective Material as Substrate, 22: Glass Cloth.

1. An ultraviolet reflective material comprising an ultraviolet reflective layer containing a condensation-cured silicone resin and ultraviolet reflective filler particles, wherein the ultraviolet reflective material has a reflectance of at least 60% at a wavelength of 405 nm thereby.

2. The ultraviolet reflective material according to claim 1, wherein the ultraviolet reflective filler particles are of alumina, magnesium hydroxide, calcium fluoride, aluminum hydroxide, aluminum nitride, and/or silicon oxide.

3. The ultraviolet reflective material according to claim 1, wherein the ultraviolet reflective material has a reflectance of at least 60% at a wavelength of 315 nm.

4. The ultraviolet reflective material according to claim 1, wherein the ultraviolet reflective material has a reflectance of at least 60% at a wavelength of 280 nm.

5. The ultraviolet reflective material according to claim 1, wherein the ultraviolet reflective material has a reflectance of at least 50% at a wavelength of 250 nm.

6. The ultraviolet reflective material according to claim 1, wherein the ultraviolet reflective material has a reflectance of at least 40% at a wavelength of 200 nm.

7. The ultraviolet reflective material according to claim 1, wherein the ultraviolet reflective material includes neither titanium oxide nor potassium titanate nor barium sulfate.

8. The ultraviolet reflective material according to claim 1, wherein the ultraviolet reflective filler particles have an average particle diameter as a median diameter of 0.05 to 50 μm.

9. The ultraviolet reflective material according to claim 1, wherein the ultraviolet reflective layer has a thickness of 1 to 2000 μm.

10. The ultraviolet reflective material according to claim 1, wherein the condensation-cured silicone resin is cured by heat.

11. The ultraviolet reflective material according to claim 1, wherein the condensation-cured silicone resin includes at least an M unit, a D unit, and a T unit as main ingredients, among the T unit as a mono-organosiloxy unit consisting of an RSiO3/2 unit (wherein an organo group R is the same or different, and is a group from an alkyl group, an aryl group, or a crosslinkable functional group), a Q unit as a siloxy unit consisting of an SiO2 unit, the M unit as a tri-organosiloxy unit consisting of an R3SiO1/2 unit (wherein R is the same as above), and the D unit as a di-organosiloxy unit consisting of an R2SiO unit (wherein R is the same as above).

12. The ultraviolet reflective material according to claim 1, wherein the ultraviolet reflective layer is attached to a film-shaped, plate-shaped, or three-dimensionally shaped support formed of any one of inorganic material selected from alumina, glass, aluminum, copper, nickel, aluminum, aluminum nitride, copper, stainless steel, and ceramics, or any one of organic material selected from imide resins, bismaleimide-triazine resins, glass fiber-containing epoxy resins, paper phenol resins, bakelite, polyethylene terephthalate resins, polybutylene terephthalate resins, polyacrylonitrile resins, polycarbonate resins, fluororesins, polyimide resins, polyphenylene sulfide resins, aramid resins, polyether ether resins, polyetherimide resins, liquid crystal polymers, polyether sulfone resins, cycloolefin resins, silicone rubbers, and silicone resins.

13. The ultraviolet reflective material according to claim 1, wherein an electrically conductive pattern is attached on a front surface or a back surface of the ultraviolet reflective layer.

14. The ultraviolet reflective material according to claim 13, wherein the electrically conductive pattern is exposed at a polished surface of the ultraviolet reflective layer covering the support having the electrically conductive pattern.

15. The ultraviolet reflective material according to claim 13, wherein the support having the electrically conductive pattern is partially covered with the ultraviolet reflective layer.

16. The ultraviolet reflective material according to claim 13, wherein the electrically conductive pattern is of a metal film.

17. A method of producing an ultraviolet reflective layer comprising:
mixing for dispersion and inclusion a condensation-curable silicone resin raw material curable into a condensation-cured silicone resin by condensation and ultraviolet reflective filler particles to prepare a liquid, or greasy and viscus or plastic raw material composition of an ultraviolet reflective material;
and then polymerizing the raw material composition into the silicone resin by three-dimensional crosslinking to form a film-shaped, three-dimensionally shaped, or plate-shaped ultraviolet reflective layer,
wherein the ultraviolet reflective layer has a reflectance of at least 60% at a wavelength of 405 nm after the curing.

18. An ultraviolet reflective material composition for forming an ultraviolet reflective layer, containing a condensation-curable silicone resin raw material curable into a condensation-cured silicone resin by condensation and ultraviolet reflective filler particles with dispersion,
wherein the ultraviolet reflective material composition is liquid, greasy and viscus or plastic for forming a ultraviolet reflecting layer having a reflectance of at least 60% at a wavelength of 405 nm after the curing.
